(19) United States
(12) Patent Application Publication
(10) Pub. No.: US 2026/0313876 A1
(43) Pub. Date: Oct. 8, 2026

(54) CAPACITOR STRUCTURE AND SEMICONDUCTOR DEVICE INCLUDING THE SAME

(71) Applicant: SAMSUNG ELECTRONICS CO., LTD., Suwon-si (KR)

(72) Inventors: Jung Woo KANG, Suwon-si (KR); Dong Hyun KIM, Suwon-si (KR); Beom Seok KIM, Suwon-si (KR); Jin Hong KIM, Suwon-si (KR); Jae Ho LEE, Suwon-si (KR)

(73) Assignee: SAMSUNG ELECTRONICS CO., LTD., Suwon-si (KR)

(21) Appl. No.: 19/461,984

(22) Filed: Jan. 28, 2026

(30) Foreign Application Priority Data
Mar. 5, 2025 (KR) 10-2025-0028084

(51) Int. Cl. H10B 12/00; H10D 1/68

(52) U.S. Cl. CPC H10B 12/315; H10D 1/714; H10D 1/694

(57) ABSTRACT

A capacitor structure according to some embodiments of the present disclosure includes an electrode structure including a first electrode and a second electrode on the first electrode, a dielectric film disposed between the first electrode and the second electrode. The dielectric film includes a rutile phase material and has a first thickness, a first interfacial insulating film disposed between the first electrode and the dielectric film and having a second thickness smaller than the first thickness, and a first inserted insulating film disposed between the first electrode and the first interfacial insulating film and having a third thickness smaller than the second thickness.

### CROSS-REFERENCE TO RELATED APPLICATION

This application claims priority from Korean Patent Application No. 10-2025-0028084 filed on Mar. 5, 2025 in the Korean Intellectual Property Office, and all the benefits accruing therefrom under 35 U.S.C. 119, the contents of which in its entirety are herein incorporated by reference.

### BACKGROUND

### 1. Field

The present disclosure relates to a capacitor structure and a semiconductor device including the same.

### 2. Description of Related Art

A size of an information storage structure of a semiconductor device is also becoming more miniaturized due to the demand for high integration and miniaturization of the semiconductor device. Accordingly, various studies have been attempted to optimize a structure of the information storage structure capable of storing information therein in a DRAM (Dynamic random-access memory).

### SUMMARY

The technical purpose to be achieved by the present disclosure is to provide a capacitor structure having improved electrical characteristics and reliability.

Another technical purpose to be achieved by the present disclosure is to provide a semiconductor device with improved electrical characteristics and reliability.

The technical purposes of the present disclosure are not limited to the technical purposes mentioned above, and other technical purposes not mentioned may be clearly understood by those skilled in the art from the following description.

A capacitor structure according to some embodiments of the present disclosure includes an electrode structure including a first electrode and a second electrode on the first electrode, a dielectric film disposed between the first electrode and the second electrode. The dielectric film includes a rutile phase material and has a first thickness, a first interfacial insulating film disposed between the first electrode and the dielectric film and having a second thickness smaller than the first thickness, and a first inserted insulating film disposed between the first electrode and the first interfacial insulating film and having a third thickness smaller than the second thickness.

A capacitor structure according to some embodiments of the present disclosure includes an electrode structure including a first electrode and a second electrode on the first electrode, a dielectric film disposed between the first electrode and the second electrode, wherein the dielectric film includes a rutile phase material and has a first thickness, a first interfacial insulating film disposed between the first electrode and the dielectric film and having a second thickness smaller than the first thickness, and a first inserted insulating film disposed between the first electrode and the first interfacial insulating film and having a third thickness smaller than the second thickness.

A semiconductor device according to some embodiments of the present disclosure includes a substrate including a first source/drain area, a second source/drain area, and a word line trench defined between the first source/drain area and the second source/drain area, a buried word line disposed in the word line trench, a bit line connected to the first source/drain area; and a capacitor structure connected to the second source/drain area. The capacitor structure includes an electrode structure including a lower electrode and an upper electrode on the lower electrode, and a dielectric film structure disposed between the lower electrode and the upper electrode. The dielectric film structure includes a dielectric film including a rutile phase material and having a first thickness, an interfacial insulating film disposed between the lower electrode and the dielectric film and having a second thickness smaller than the first thickness, and an inserted insulating film disposed between the lower electrode and the interfacial insulating film, the inserted insulating film having a third thickness smaller than the second thickness.

Specific details of other embodiments are included in the detailed description and drawings.

### BRIEF DESCRIPTION OF DRAWINGS

The above and other aspects and features of the present disclosure will become more apparent by describing in detail embodiments thereof with reference to the attached drawings, in which:

FIG. 1 is a schematic layout diagram for illustrating a semiconductor device according to some embodiments;

FIG. 2 is a cross-sectional view taken along a line I-I′ of FIG. 1;

FIG. 3 is a cross-sectional view taken along a line II-II′ of FIG. 1;

FIG. 4 is an enlarged view of an area A1 of FIG. 3;

FIG. 5 is an enlarged view of an area A2 of FIG. 4;

FIG. 6 is a diagram for illustrating a semiconductor device according to some embodiments, and is a diagram corresponding to FIG. 5;

FIG. 7 is a diagram for illustrating a semiconductor device according to some embodiments, and is a diagram corresponding to FIG. 5;

FIG. 8 is a diagram for illustrating a semiconductor device according to some embodiments, and corresponds to FIG. 5;

FIGS. 9 to 18 are diagrams of intermediate structures corresponding to intermediate steps of a method for manufacturing a semiconductor device according to some embodiments;

FIG. 19 is an enlarged view of an area A1′ of FIG. 18;

FIG. 20 is a schematic layout diagram for illustrating a semiconductor device according to some embodiments;

FIG. 21 is a cross-sectional view taken along lines X1-X1′ and Y1-Y1′ of FIG. 20

FIG. 22 is a cross-sectional view of a semiconductor device according to some embodiments;

FIG. 23 is an example diagram for illustrating a semiconductor device according to some embodiments;

FIG. 24 is an example diagram for illustrating a semiconductor device according to some embodiments.

### DETAILED DESCRIPTIONS

Hereinafter, embodiments according to the technical idea of the present disclosure will be described with reference to the accompanying drawings.

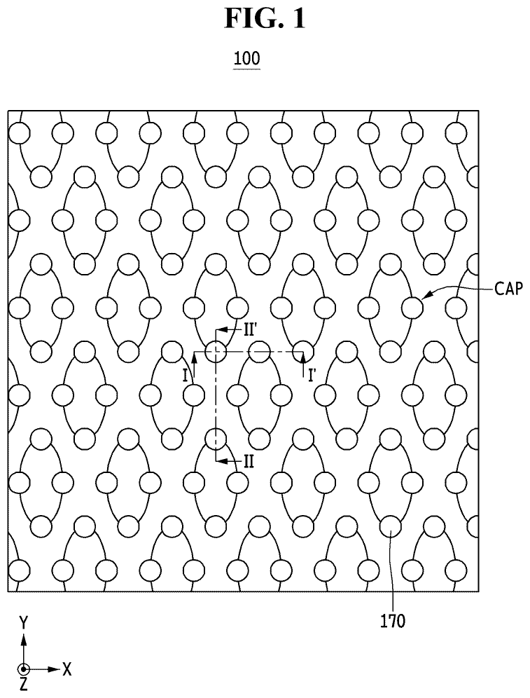

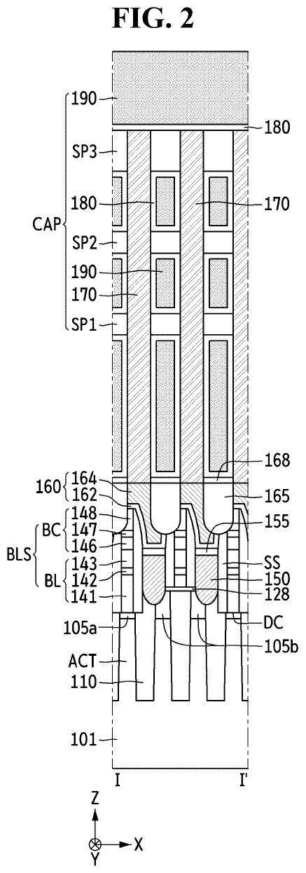

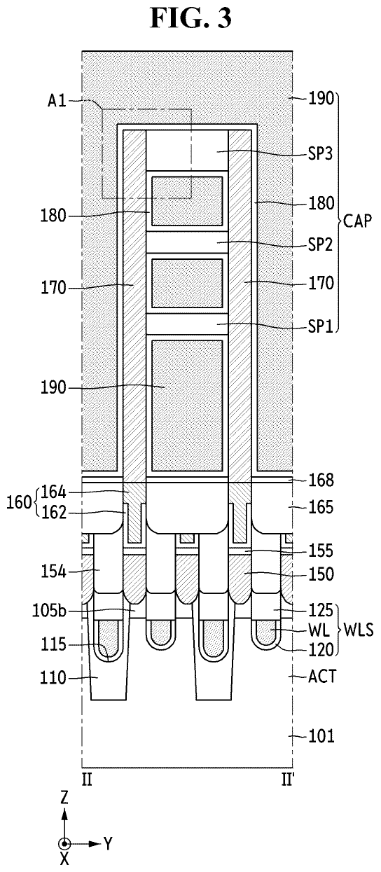

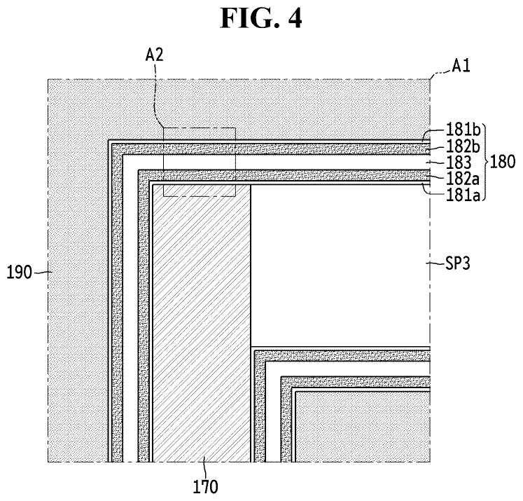

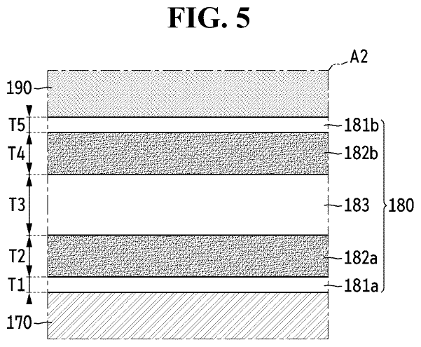

FIG. 1 is a schematic layout diagram for illustrating a semiconductor device according to some embodiments. FIG. 2 is a cross-sectional view taken along a line I-I′ of FIG. 1. FIG. 3 is a cross-sectional view taken along a line II-II′ of FIG. 1. FIG. 4 is an enlarged view of an area A1 of FIG. 3. FIG. 5 is an enlarged view of an area A2 of FIG. 4.

Referring to FIGS. 1 to 3, a semiconductor device 100 according to some embodiments may include a substrate 101 including active areas ACT, an element isolation layer 110 defining each of the active areas ACT in the substrate 101, a word line structure WLS buried in and extending in the substrate 101 and including a word line WL, a bit line structure BLS disposed on the substrate 101 so as to extend to intersect the word line structure WLS and including a bit line BL, and an information storage structure CAP on the bit line structure BLS.

The information storage structure CAP may store information therein, and may be, for example, a capacitor structure of DRAM. The semiconductor device 100 may further include a lower conductive pattern 150 disposed on the active area ACT, an upper conductive pattern 160 disposed on the lower conductive pattern 150, and an insulating pattern 165 extending through the upper conductive pattern 160.

The semiconductor device 100 may include, for example, a cell array of a dynamic random access memory (DRAM). For example, the bit line BL may be connected to a first impurity area 105a of the active area ACT, while a second impurity area 105b of the active area ACT may be electrically connected to the information storage structure CAP disposed on the upper conductive pattern 160 via the lower and upper conductive patterns 150 and 160.

The information storage structure CAP may be a capacitor capable of storing information therein in a memory such as a DRAM. The information storage structure CAP may be electrically connected to the conductive areas 150 and 160 while being disposed on a lower structure including the conductive areas 150 and 160, for example, the lower and upper conductive patterns 150 and 160. In this regard, the lower structure may include the substrate 101, the word line structure WLS, the bit line structure BLS, etc.

The information storage structure CAP may include first electrode structures 170, a dielectric film structure 180 disposed on the first electrode structures 170, and a second electrode structure 190 disposed on the dielectric film structure 180. The information storage structure CAP may further include supporter layers SP1, SP2, and SP3. The first electrode structures 170 may be lower electrodes, and the second electrode structure 190 may be an upper electrode.

Although not shown specifically, the semiconductor device 100 may include a cell array area in which a cell array is disposed and a peripheral circuit area in which peripheral circuits for driving the memory cells disposed in the cell array are disposed. The peripheral circuit area may be disposed around the cell array area.

The substrate 101 may include a semiconductor material, for example, a group IV semiconductor, a group III-V compound semiconductor, or a group II-VI compound semiconductor. For example, the IV group semiconductor may include silicon, germanium, or silicon-germanium. The substrate 101 may further include impurities. The substrate 101 may be a silicon substrate, a silicon on insulator (SOI) substrate, a germanium substrate, a germanium on insulator (GOI) substrate, a silicon-germanium substrate, or a substrate including an epitaxial layer.

The active areas ACT may be disposed in the substrate 101 and may be defined by the element isolation layer 110. The active area ACT may have a bar shape and may be disposed in the substrate 101 and may have an island shape extending in one direction. The one direction may be inclined with respect to an extension direction of each of the word lines WL and the bit lines BL. The active areas ACT may be arranged in a parallel manner to each other, and an end of one active area ACT may be positioned to be adjacent to a center of another active area ACT adjacent thereto.

The active area ACT may have the first and second impurity areas 105a and 105b having a predetermined depth from an upper surface of the substrate 101. The first and second impurity areas 105a and 105b may be spaced apart from each other. The first and second impurity areas 105a and 105b may be provided as source/drain areas of a transistor including the word line WL. The source area and the drain area may be embodied as the first and second impurity areas 105a and 105b formed by doping or ion implantation of substantially the same impurities. The names of the source area and the drain area may be exchanged with each other depending on a circuit configuration of a transistor to be finally formed. The impurities may include impurities having a conductivity type opposite to that of the substrate 101. In some embodiments, depths of the first and second impurity areas 105a and 105b in the source area SA and the drain area DA may be different from each other.

The element isolation layer 110 may be formed by a shallow trench isolation (STI) process. The element isolation layer 110 may surround each of the active areas ACT and may electrically isolate the active areas ACT from each other. The element isolation layer 110 may be made of an insulating material, for example, silicon oxide, silicon nitride, or a combination thereof. The element isolation layer 110 may include a plurality of areas having different depths of lower ends thereof depending on widths of trenches formed by etching the substrate 101.

The word line structures WLS may be respectively disposed in gate trenches 115 defined in the substrate 101 and extending therein. Each of the word line structures WLS may include a gate dielectric film 120, a word line WL, and a gate capping film 125. As used herein, the “gate” may be referred to as a structure including the gate dielectric film 120 and the word line WL, the word line WL may be referred to as a “gate electrode”, and the word line structure WLS may be referred to as a “gate structure”.

The word line WL may extend in the first direction X and across the active area ACT. For example, a pair of word lines WL adjacent to each other may intersect one active area ACT. The word line WL may constitute a gate of a buried channel array transistor (BCAT). However, embodiments of the present disclosure are not limited thereto. In some embodiments, the word lines WL may be disposed on the substrate 101. The word line WL may be disposed under the gate trench 115 and may have a predetermined thickness. An upper surface of the word line WL may be located at a lower vertical level than that of the upper surface of the substrate 101. As used herein, the term “vertical level” may be defined based on a substantially flat upper surface of the substrate 101.

The word line WL may include a conductive material, for example, at least one of polycrystalline silicon (Si), titanium (Ti), titanium nitride (TiN), tantalum (Ta), tantalum nitride (TaN), tungsten (W), tungsten nitride (WN), and aluminum (Al). For example, the word line WL may include a lower pattern and an upper pattern made of different materials. In this case, the lower pattern may include at least one of tungsten (W), titanium (Ti), tantalum (Ta), tungsten nitride (WN), titanium nitride (TiN), and tantalum nitride (TaN), and the upper pattern may be a semiconductor pattern including polysilicon doped with P-type or N-type impurities.

The gate dielectric film 120 may be disposed on a bottom surface and inner side surfaces of the gate trench 115. The gate dielectric film 120 may conformally cover an inner sidewall of the gate trench 115. The gate dielectric film 120 may include at least one of silicon oxide, silicon nitride, and silicon oxynitride. The gate dielectric film 120 may be, for example, a silicon oxide film or an insulating film having a higher dielectric constant than that of the silicon oxide film. In some embodiments, the gate dielectric film 120 may be formed by oxidizing the active area ACT, or may be formed by deposition.

The gate capping film 125 may be disposed on the word line WL so as to fill the gate trench 115. An upper surface of the gate capping film 125 may be located at substantially the same vertical level as that of the upper surface of the substrate 101. The gate capping film 125 may be made of an insulating material, for example, silicon nitride.

The bit line structure BLS may extend in a direction perpendicular to the word line WL, for example, the second direction Y. The bit line structure BLS may include a bit line BL and a bit line capping pattern BC disposed on the bit line BL.

The bit line BL may include a first conductive pattern 141, a second conductive pattern 142, and a third conductive pattern 143 which are sequentially stacked. The bit line capping pattern BC may be disposed on the third conductive pattern 143. A buffer insulating layer 128 may be disposed between the first conductive pattern 141 and the substrate 101, and a portion of (hereinafter, referred to as a bit line contact pattern DC) of the first conductive pattern 141 may be in contact with the first impurity area 105a of the active area ACT.

The bit line BL may be electrically connected to the first impurity area 105a via the bit line contact pattern DC. A lower surface of the bit line contact pattern DC may be located at a lower vertical level than a vertical level of the upper surface of the substrate 101, and may be located at a higher vertical level than a vertical level of an upper surface of the word line WL. In some embodiments, the bit line contact pattern DC may be formed in the substrate 101 and may be at least partially disposed in a bit line contact hole exposing the first impurity area 105a.

The first conductive pattern 141 may include a semiconductor material such as polycrystalline silicon. The first conductive pattern 141 may directly contact the first impurity area 105a. The second conductive pattern 142 may include a metal-semiconductor compound. The metal-semiconductor compound may be obtained, for example, by converting a portion of the first conductive pattern 141 into metal silicide.

For example, the metal-semiconductor compound may include cobalt silicide (CoSi), titanium silicide (TiSi), nickel silicide (NiSi), tungsten silicide (WSi), or other metal silicide. The third conductive pattern 143 may include a metal material such as titanium (Ti), tantalum (Ta), tungsten (W), and aluminum (Al). The number of conductive patterns constituting the bit line BL, the type of material thereof, and/or a stacking order thereof may be variously changed according to embodiments.

The bit line capping pattern BC may include a first capping pattern 146, a second capping pattern 147, and a third capping pattern 148 which are sequentially stacked on the third conductive pattern 143. Each of the first to third capping patterns 146, 147, and 148 may include an insulating material, for example, a silicon nitride film. The first to third capping patterns 146, 147, and 148 may be made of different materials. Even when the first to third capping patterns 146, 147, and 148 include the same material, boundaries between first to third capping patterns 146, 147, and 148 may be defined due to differences in physical properties thereof.

A thickness of the second capping pattern 147 may be smaller than a thickness of each of the first capping pattern 146 and the third capping pattern 148. The number of capping patterns constituting the bit line capping pattern BC and/or the type of material thereof may be variously changed according to embodiments.

Spacer structures SS may be respectively disposed on both opposing sidewalls of each of the bit line structures BLS and may extend in one direction, for example, the second direction Y. The spacer structures SS may be disposed between the bit line structure BLS and the lower conductive pattern 150. The spacer structures SS may extend along sidewalls of the bit line BL and sidewalls of the bit line capping pattern BC.

A pair of spacer structures SS respectively disposed on both opposing sides of one bit line structure BLS may have an asymmetric shape with respect to each other around the bit line structure BLS. Each of the spacer structures SS may include a plurality of spacer layers, and may further include an air gap according to embodiments.

The lower conductive pattern 150 may be connected to an area of the active area ACT, for example, the second impurity area 105b. The lower conductive pattern 150 may be disposed between the bit lines BL and between the word lines WL. The lower conductive pattern 150 may extend through the buffer insulating layer 128 so as to be connected to the second impurity area 105b of the active area ACT. The lower conductive pattern 150 may be in direct contact with the second impurity area 105b.

A lower surface of the lower conductive pattern 150 may be located at a lower vertical level than a vertical level of the upper surface of the substrate 101, and may be located at a higher vertical level than a vertical level of a lower surface of the bit line contact pattern DC. The lower conductive pattern 150 may be insulated from the bit line contact pattern DC via the spacer structure SS.

The lower conductive pattern 150 may be made of a conductive material, and may include, for example, at least one of polycrystalline silicon (Si), titanium (Ti), titanium nitride (TiN), tantalum (Ta), tantalum nitride (TaN), tungsten (W), tungsten nitride (WN), and aluminum (Al). In some embodiments, the lower conductive pattern 150 may include a plurality of layers.

A metal-semiconductor compound layer 155 may be disposed between the lower conductive pattern 150 and the upper conductive pattern 160. For example, when the lower conductive pattern 150 includes a semiconductor material, the metal-semiconductor compound layer 155 may be a layer obtained by converting a portion of the lower conductive pattern 150 into silicide. The metal-semiconductor compound layer 155 may include, for example, cobalt silicide (CoSi), titanium silicide (TiSi), nickel silicide (NiSi), tungsten silicide (WSi), or other metal silicide. In some embodiments, the metal-semiconductor compound layer 155 may be omitted.

The upper conductive pattern 160 may be disposed on the lower conductive pattern 150. The upper conductive pattern 160 may extend into an area between the spacer structures SS so as to cover an upper surface of the metal-semiconductor compound layer 155. The upper conductive pattern 160 may include a barrier layer 162 and a conductive layer 164. The barrier layer 162 may cover a lower surface and side surfaces of the conductive layer 164.

The barrier layer 162 may include a metal nitride, for example, at least one of titanium nitride (TiN), tantalum nitride (TaN), and tungsten nitride (WN). The conductive layer 164 may include a conductive material, for example, at least one of polycrystalline silicon (Si), titanium (Ti), tantalum (Ta), tungsten (W), ruthenium (Ru), copper (Cu), molybdenum (Mo), platinum (Pt), nickel (Ni), cobalt (Co), aluminum (Al), titanium nitride (TiN), tantalum nitride (TaN), and tungsten nitride (WN).

The insulating patterns 165 may be disposed to extend through the upper conductive pattern 160. The insulating patterns 165 may divide the upper conductive pattern 160 into a plurality of portions. The insulating patterns 165 may include an insulating material, for example, at least one of silicon oxide, silicon nitride, and silicon oxynitride.

An etch stop layer 168 may cover the insulating patterns 165 while being disposed between the first electrode structures 170. The etch stop layer 168 may be in contact with lower areas of side surfaces of the first electrode structures 170. The etch stop layer 168 may be disposed under the supporter layers SP1, SP2, and SP3. An upper surface of the etch stop layer 168 may include a portion that is in direct contact with the dielectric film structure 180. The etch stop layer 168 may include, for example, at least one of silicon nitride and silicon oxynitride.

The first electrode structures 170 may be disposed on the upper conductive patterns 160. The first electrode structures 170 may extend through the etch stop layer 168 so as to be in contact with the upper conductive patterns 160. Each of the first electrode structures 170 may have a pillar shape. However, embodiments of the present disclosure are not limited thereto. For example, each of the first electrode structures 170 may include at least one of Pt, Ir, Ru, Mo, V, TiN, NbN, TiSiN, MoN, VN, and ScN, or a combination thereof. However, embodiments of the present disclosure are not limited thereto.

The dielectric film structure 180 may cover side and upper surfaces of each of the first electrode structures 170 while being disposed on the surfaces of the first electrode structures 170. The dielectric film structure 180 may be disposed between the first electrode structures 170 and the second electrode structure 190. The dielectric film structure 180 may cover upper and lower surfaces of the supporter layers SP1, SP2, and SP3. The dielectric film structure 180 may cover an upper surface of the etch stop layer 168. The dielectric film structure 180 may include a high-k material, silicon oxide, silicon nitride, or a combination thereof. The detailed structure and material of the dielectric film structure 180 will be described later in detail with reference to FIGS. 4 and 5.

The second electrode structure 190 may cover the first electrode structures 170, the supporter layers SP1, SP2, and SP3, and the dielectric film structure 180. The second electrode structure 190 may extend along a surface of the dielectric film structure 180. The second electrode structure 190 may fill a space between adjacent ones of the first electrode structures 170 and a space between adjacent ones of the supporter layers SP1, SP2, and SP3.

The second electrode structure 190 may include a conductive material. For example, the second electrode structure 190 may include a conductive metal nitride (e.g., titanium nitride, tantalum nitride, niobium nitride, tungsten nitride, or the like), a metal (e.g., ruthenium, iridium, titanium, tantalum, or the like), a conductive metal oxide (e.g., iridium oxide, niobium oxide, or the like), etc. However, the technical idea of the present disclosure is not limited thereto. For example, the second electrode structure 190 may include at least one of Pt, Ir, Ru, Mo, V, TiN, NbN, TiSiN, MoN, VN, and ScN, or a combination thereof. However, embodiments of the present disclosure are not limited thereto.

In another example, the second electrode structure 190 may include a silicon material or a silicon-germanium material. In this case, the second electrode structure 190 may include doped silicon or doped silicon-germanium.

The supporter layers SP1, SP2, and SP3 may include a first supporter layer SP1, a second supporter layer SP2 disposed on the first supporter layer SP1, and a third supporter layer SP3 disposed on the second supporter layer SP2. The supporter layers SP1, SP2, and SP3 may be arranged to be spaced apart from the substrate 101 in a direction perpendicular to the upper surface of the substrate 101, that is, in a third direction Z. The supporter layers SP1, SP2, and SP3 may be in contact with the first electrode structures 170 and may extend in a direction parallel to the upper surface of the substrate 101, that is, in first and second directions X and Y.

Each of the supporter layers SP1, SP2, and SP3 may include a portion in direct contact with the first electrode structures 170 and the dielectric film structure 180. The third supporter layer SP3 may have a thickness greater than that of each of the first supporter layer SP1 and the second supporter layer SP2. However, embodiments of the present disclosure are not limited thereto. The supporter layers SP1, SP2, and SP3 may support the first electrode structures 170 having a high aspect ratio.

Each of the supporter layers SP1, SP2, and SP3 may include, for example, at least one of silicon nitride and silicon oxynitride. The number, thickness, and/or arrangement relationship of the supporter layers SP1, SP2, and SP3 are not limited to those as illustrated, and may be variously changed according to embodiments.

At least one supporter layer SP1, SP2, and SP3 supporting the first electrode structures 170 may be provided between the adjacent first electrode structures 170. For example, the first supporter layer SP1, the second supporter layer SP2, and the third supporter layer SP3, which are in contact with the first electrode structures 170 may be provided between adjacent first electrode structures 170.

Referring to FIG. 1, in a top view, the first electrode structures 170 may have a regular arrangement. In some embodiments, the first electrode structures 170 may be spaced apart from each other by a predetermined distance in the first direction X, and may be arranged in a zigzag manner in the second direction Y. However, the arrangement of the first electrode structures 170 is not limited thereto.

A through-hole pattern may be disposed between a plurality of adjacent first electrode structures 170. In some embodiments, as illustrated in the semiconductor device 100 of FIG. 1, one through-hole pattern may be disposed between four adjacent first electrode structures 170. However, the arrangement of the through-hole patterns is not limited thereto.

Referring to FIGS. 4 and 5, the dielectric film structure 180 may include a first inserted insulating film 181a, a first interfacial insulating film 182a, a dielectric film 183, a second interfacial insulating film 182b, and a second inserted insulating film 181b which are sequentially stacked.

The first inserted insulating film 181a may be disposed between the first electrode structure 170 and the first interfacial insulating film 182a. The first inserted insulating film 181a may be disposed along an upper surface of the etch stop layer 168, a side surface of the first electrode structure 170, and an upper surface of the first electrode structure 170. The first inserted insulating film 181a may be in contact with the upper surface of the etch stop layer 168, the side surface of the first electrode structure 170, and the upper surface of the first electrode structure 170.

The first inserted insulating film 181a may be disposed on a lower surface and an upper surface of the first supporter layer SP1, a lower surface and an upper surface of the second supporter layer SP2, and a lower surface and an upper surface of the third supporter layer SP3. The first inserted insulating film 181a may be in contact with the lower surface and the upper surface of the first supporter layer SP1, the lower surface and the upper surface of the second supporter layer SP2, and the lower surface and the upper surface of the third supporter layer SP3.

The first interfacial insulating film 182a may be disposed between the first inserted insulating film 181a and the dielectric film 183. The first interfacial insulating film 182a may be disposed on the first inserted insulating film 181a and along the upper surface of the etch stop layer 168, the side surface of the first electrode structure 170, and the upper surface of the first electrode structure 170. The first interfacial insulating film 182a may be disposed on the first inserted insulating film 181a, on the lower surface and the upper surface of the first supporter layer SP1, on the lower surface and the upper surface of the second supporter layer SP2, and on the lower surface and the upper surface of the third supporter layer SP3.

The dielectric film 183 may be disposed between the first electrode structure 170 and the second electrode structure 190. The dielectric film 183 may be disposed between the first interfacial insulating film 182a and the second interfacial insulating film 182b. The dielectric film 183 may be disposed on the first interfacial insulating film 182a and along the upper surface of the etch stop layer 168, the side surface of the first electrode structure 170, and the upper surface of the first electrode structure 170. The dielectric film 183 may be disposed on the first interfacial insulating film 182a, on the lower surface and the upper surface of the first supporter layer SP1, on the lower surface and the upper surface of the second supporter layer SP2, and on the lower surface and the upper surface of the third supporter layer SP3. Although not specifically shown, the dielectric film 183 may be formed in a multilayer structure in which layers made of different materials are stacked.

The second interfacial insulating film 182b may be disposed between the dielectric film 183 and the second inserted insulating film 181b. The second interfacial insulating film 182b may be disposed on the dielectric film 183 and along the upper surface of the etch stop layer 168, the side surface of the first electrode structure 170, and the upper surface of the first electrode structure 170. The second interfacial insulating film 182b may be disposed on the dielectric film 183, on the lower surface and the upper surface of the first supporter layer SP1, on the lower surface and the upper surface of the second supporter layer SP2, and on the lower surface and the upper surface of the third supporter layer SP3.

The second inserted insulating film 181b may be disposed between the second interfacial insulating film 182b and the second electrode structure 190. The second inserted insulating film 181b may be disposed on the second interfacial insulating film 182b and along the upper surface of the etch stop layer 168, the side surface of the first electrode structure 170, and the upper surface of the first electrode structure 170. The second inserted insulating film 181b may be disposed on the second interfacial insulating film 182b, on the lower surface and the upper surface of the first supporter layer SP1, on the lower surface and the upper surface of the second supporter layer SP2, and on the lower surface and the upper surface of the third supporter layer SP3.

In the third direction Z perpendicular to each of the first and second directions X and Y, the first inserted insulating film 181a may have a first thickness T1, the first interfacial insulating film 182a may have a second thickness T2, and the dielectric film 183 may have a third thickness T3. The second thickness T2 may be greater than the first thickness T1 and smaller than the third thickness T3. For example, the first thickness T1 may be within 5 angstroms. More specifically, for example, the first thickness T1 may be in a range of 1 angstrom to 3 angstroms, the second thickness T2 may be in a range of 1 nm to 4 nm, and the third thickness T3 may be in a range of 4 nm to 1 um. However, embodiments of the present disclosure are not limited thereto.

In the third direction Z, the second interfacial insulating film 182b may have a fourth thickness T4, and the second inserted insulating film 181b may have a fifth thickness T5. The fourth thickness T4 may be greater than the fifth thickness T5 and smaller than the third thickness T3. For example, the fifth thickness T5 may be within 5 angstroms. More specifically, for example, the fifth thickness T5 may be in a range of 1 angstrom to 3 angstroms, and the fourth thickness T4 may be in a range of 1 nm to 4 nm. However, embodiments of the present disclosure are not limited thereto. For example, the fourth thickness T4 may be equal to the second thickness T2, and the fifth thickness T5 may be equal to the first thickness T1. However, embodiments of the present disclosure are not limited thereto.

The dielectric film 183 may include a material having a rutile phase. The dielectric film 183 may include a metal oxide having a rutile crystal structure. The first interfacial insulating film 182a may include a rutile phase material. The first interfacial insulating film 182a may include a metal oxide having a rutile crystal structure. The dielectric film 183 and the first interfacial insulating film 182a may include the same metal oxide or different metal oxides.

For example, the first interfacial insulating film 182a may include the same rutile-phase material as that included in the dielectric film 183. The first interfacial insulating film 182a may include the metal oxide having the same rutile crystal structure as that included in the dielectric film 183.

On the contrary, the first inserted insulating film 181a may not include the rutile phase material included in the dielectric film 183 and the first interfacial insulating film 182a. The first inserted insulating film 181a may not include a metal oxide having a rutile crystal structure included in the dielectric film 183 and the first interfacial insulating film 182a. The first inserted insulating film 181a may include an amorphous material.

The dielectric film 183 may include a first material having a first oxidation number. For example, the first material may be a metal oxide having the first oxidation number. The first interfacial insulating film 182a may include a second material having a second oxidation number, and may further include a third material having a third oxidation number. For example, the second material may be a metal oxide having the same oxidation number as the first oxidation number, and the third material may be a material having a different oxidation number from the first oxidation number. A content of the second material in the first interfacial insulating film 182a may be higher than a content of the third material in the first interfacial insulating film 182a. As used herein, the term “the content” of the material means a content of a material per unit volume.

On the contrary, the first inserted insulating film 181a may include a material having an oxidation number different from that of the material included in each of the dielectric film 183 and the first interfacial insulating film 182a.

The second interfacial insulating film 182b may include the same rutile phase material as that included in the dielectric film 183. The second interfacial insulating film 182b may include the metal oxide having the same rutile crystal structure as that included in the dielectric film 183. The dielectric film 183 and the second interfacial insulating film 182b may include the same metal oxide or different metal oxides.

On the contrary, the second inserted insulating film 181b may not include the rutile phase material included in each of the dielectric film 183 and the second interfacial insulating film 182b. The second inserted insulating film 181b may not include a metal oxide having a rutile crystal structure included in each of the dielectric film 183 and the second interfacial insulating film 182b. The second inserted insulating film 181b may include an amorphous material.

The second interfacial insulating film 182b may include a fourth material having a fourth oxidation number, and may further include a fifth material having a fifth oxidation number. For example, the fourth material may be a metal oxide having the same oxidation number as the first oxidation number, and the fifth material may be a material having a different oxidation number from the first oxidation number. The content of the fourth material in the second interfacial insulating film 182b may be higher than the content of the fifth material therein.

On the contrary, the second inserted insulating film 181b may include a material having an oxidation number different from that of the material included each of in the dielectric film 183 and the second interfacial insulating film 182b.

The above-described description of the structure and material of the first interfacial insulating film 182a may be similarly applied to the structure and material of the second interfacial insulating film 182b.

The above-described description of the structure and material of the first inserted insulating film 181a may be similarly applied to the structure and material of the second inserted insulating film 181b.

For example, each of the first inserted insulating film 181a and the second inserted insulating film 181b may include at least one of Al₂O₃, Y₂O₃, MgO, Sc₂O₃, and SiO₂. However, embodiments of the present disclosure are not limited thereto.

For example, each of the first interfacial insulating film 182a and the second interfacial insulating film 182b may include at least one of TiO₂, NbO, MoO₂, VO₂, ScO, TaO, Al₂O₃, and SnO₂. However, embodiments of the present disclosure are not limited thereto.

For example, the dielectric film 183 may include at least one of ZrO₂, HfO₂, ZrHfO, TiO₂, Al₂O₃, GeO₂, Y₂O₃, MgO, and Sc₂O₃. However, embodiments of the present disclosure are not limited thereto.

For example, the oxidation number of the material included in each of the first inserted insulating film 181a, the first interfacial insulating film 182a, the dielectric film 183, the second interfacial insulating film 182b, and the second inserted insulating film 181b may be identified via XPS (X-ray photoelectron spectroscopy) analysis. For example, the crystallinity of the material included in each of the first inserted insulating film 181a, the first interfacial insulating film 182a, the dielectric film 183, the second interfacial insulating film 182b, and the second inserted insulating film 181b may be identified via XRD (X-ray diffraction) analysis.

It may be identified via high-angle annular dark field image (HAADF) analysis of the capacitor structure according to some embodiments that the first inserted insulating film 181a is interposed between the first interfacial insulating film 182a and the first electrode structure 170, and the second inserted insulating film 181b is interposed between the second interfacial insulating film 182b and the second electrode structure 190.

In addition, it may be identified via the transmission electron microscopy-electron microscopy-energy dispersed X-ray analysis (TEM-EDAX) image that a material included in the first inserted insulating film 181a exists between the first interfacial insulating film 182b and the first electrode structure 170, and a material included in the second inserted insulating film 181b exists between the second interfacial insulating film 182a and the second electrode structure 190.

Forming the first inserted insulating film 181a between the first interfacial insulating film 182a and the first electrode structure 170 and forming the second inserted insulating film 181b between the second interfacial insulating film 182b and the second electrode structure 190 may allow oxidation of each of the electrode structures 170 and 190 to be effectively prevented.

Accordingly, the oxygen content in each of the electrode structures 170 and 190 according to some embodiments may be smaller than the oxygen content of the electrode structure of Comparative Example in which the inserted insulating films 181a and 181b are not interposed between the interfacial insulating films 182a and 182b and the electrode structures 170 and 190.

In addition, the oxygen content in the first electrode structure 170 according to some embodiments may be smaller than the oxygen content in the first interfacial insulating film 182a. The oxygen content in the second electrode structure 190 according to some embodiments may be smaller than the oxygen content in the second interfacial insulating film 182b. As used herein, the term “oxygen content” means a content of oxygen per unit volume.

The fact that the oxygen content in the first electrode structure 170 according to some embodiments is smaller than the oxygen content in the first interfacial insulating film 182a and the oxygen content in the second electrode structure 190 is smaller than the oxygen content in the second interfacial insulating film 182b may be identified based on a result of analyzing a profile of an oxygen concentration via TEM-EDAX.

In some embodiments, the inserted insulating films 181a and 181b may be introduced to induce the interfacial insulating films 182a and 182b having a lattice structure matching a target lattice structure of the high-k dielectric film 183.

It may be identified via the XPS peak analysis of the capacitor structure according to some embodiments that the interfacial insulating films 182a and 182b are formed so as to have a lattice structure matching the lattice structure of the high-k dielectric film 183, compared to Comparative Example in which the inserted insulating films 181a and 181b are not interposed between the interfacial insulating films 182a and 182b and the electrode structures 170 and 190.

As a result, in some embodiments, a capacitor structure having improved capacitance may be provided by minimizing oxidation of the electrode structures 170 and 190 and simultaneously securing high dielectric properties of the dielectric film 183.

Further, the thickness of each of the first and second inserted insulating films 181a and 181b and the concentration of the material included in each of the first and second inserted insulating films 181a and 181b are not limited to those as described herein, and may have various values in order to secure target characteristics of the capacitor.

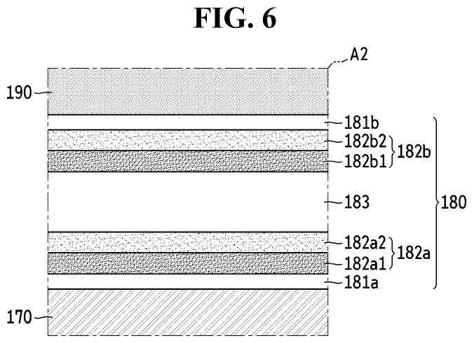

FIG. 6 is a diagram for illustrating a semiconductor device according to some embodiments, and is a diagram corresponding to FIG. 5. For convenience of description, contents duplicate with those described above with reference to FIGS. 1 to 5 will be briefly described or descriptions thereof will be omitted.

Referring to FIG. 6, each of the first interfacial insulating film 182a and the second interfacial insulating film 182b may have a multilayer structure rather than a single-layer structure.

The first interfacial insulating film 182a may include a first metal oxide layer 182a and a second metal oxide layer 182a1 sequentially stacked on the first inserted insulating film 181a2. The first metal oxide layer 182a1 may include a metal material different from that of the second metal oxide layer 182a2.

The second interfacial insulating film 182b may include a third metal oxide layer 182b and a fourth metal oxide layer 182b1 sequentially stacked on the second inserted insulating film 181b2. The third metal oxide layer 182b1 may include a metal material different from that of the fourth metal oxide layer 182b2.

In this regard, the number and thickness of metal oxide layers included in each of the interfacial insulating films 182a and 182b are not limited to those illustrated in the drawings.

Although not specifically shown, the dielectric film 183 may also have a multilayer structure rather than a single layer structure. That is, each of the dielectric film 183, the first interfacial insulating film 182a, and the second interfacial insulating film 182b may include a plurality of metal oxide layers.

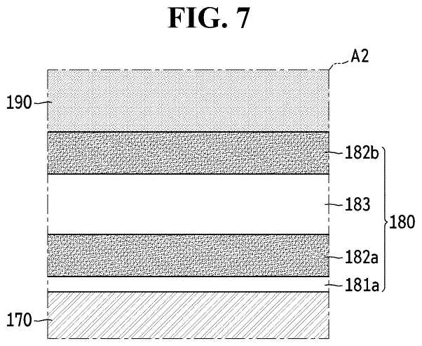

FIG. 7 is a diagram for illustrating a semiconductor device according to some embodiments, and is a diagram corresponding to FIG. 5. For convenience of description, contents duplicate with those described above with reference to FIGS. 1 to 6 will be briefly described or descriptions thereof will be omitted.

Referring to FIG. 7, an inserted insulating film may not be disposed between the second electrode structure 190 and the second interfacial insulating film 182b. The second electrode structure 190 may be disposed on the second interfacial insulating film 182b. The second electrode structure 190 may be in direct contact with the second interfacial insulating film 182b while being disposed on the second interfacial insulating film 182b.

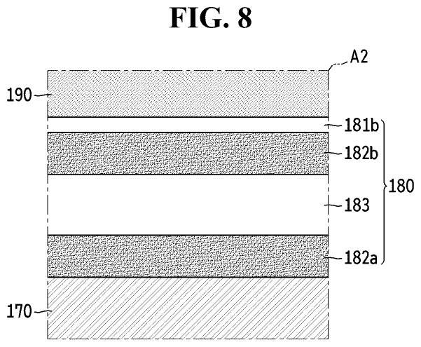

FIG. 8 is a diagram for illustrating a semiconductor device according to some embodiments, and corresponds to FIG. 5. For convenience of description, contents duplicate with those described above with reference to FIGS. 1 to 7 will be briefly described or descriptions thereof will be omitted.

Referring to FIG. 8, an inserted insulating film may not be disposed between the first electrode structure 170 and the first interfacial insulating film 182a. The first interfacial insulating film 182a may be disposed on the first electrode structure 170. The first interfacial insulating film 182a may be in direct contact with the first electrode structure 170 while being disposed on the first electrode structure 170.

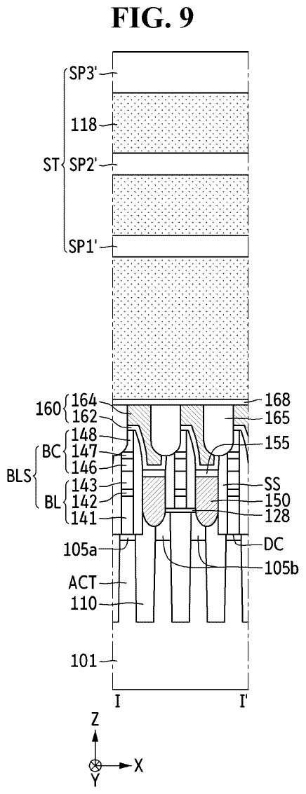

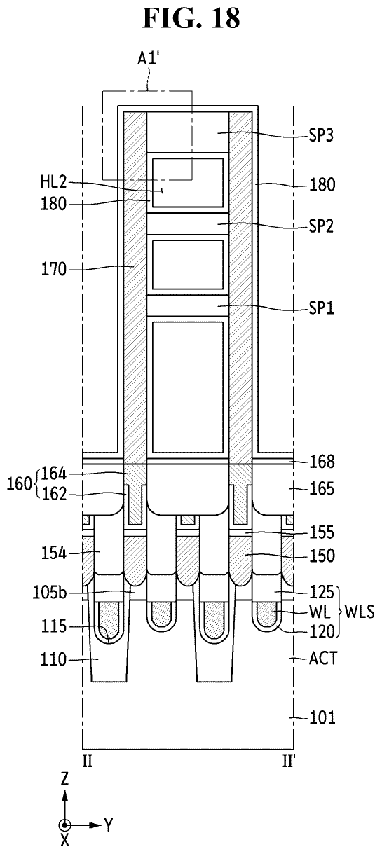

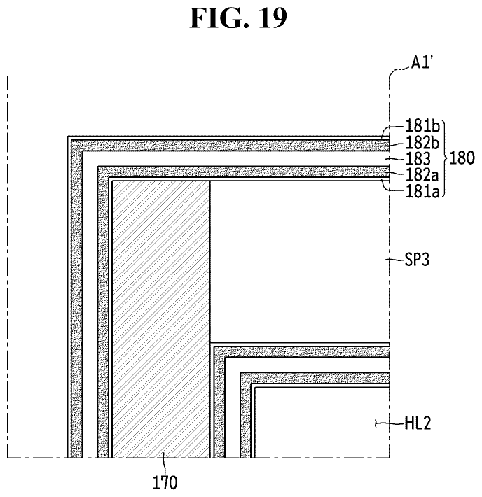

FIGS. 9 to 18 are diagrams of intermediate structures corresponding to intermediate steps of a method for manufacturing a semiconductor device according to some embodiments. FIG. 19 is an enlarged view of an area A1′ of FIG. 18. For convenience of description, contents duplicate with those described above with reference to FIGS. 1 to 8 will be briefly described or descriptions thereof will be omitted. FIGS. 9 to 18 are diagrams for describing a manufacturing method for manufacturing the semiconductor device 100 of FIGS. 2 and 3, and are diagrams corresponding to the cross-sectional view I-I′ of FIG. 2 and the cross-sectional view II-II′ of FIG. 3.

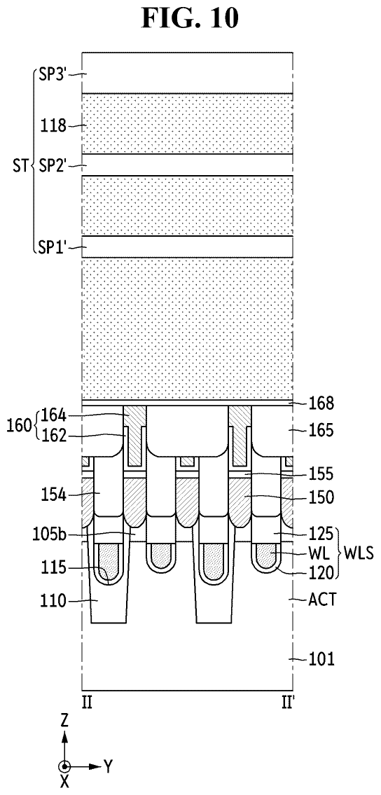

Referring to FIGS. 9 and 10, the lower structure and a mold structure ST may be formed on a substrate 101.

First, the element isolation layer 110 may be formed on the substrate 101 so as to define an active area ACT. An element isolation trench may be formed in the substrate 101, and the element isolation layer 110 may fill the element isolation trench. In a plan view, the active area ACT may have an elongated bar shape extending in a direction oblique to the extending direction of the word line WL. An ion implantation process may be performed using the element isolation layer 110 as an ion implantation mask to form impurity areas in an upper portion of the active area ACT. A gate trench 115 may be formed by patterning the active area ACT and the element isolation layer 110. A pair of gate trenches 115 may extend so as to intersect the active area ACT. However, embodiments of the present disclosure are not limited thereto. The impurity areas may also be isolated from each other via the gate trench 115 to form the first impurity area 105a and the second impurity area 105b.

The gate dielectric film 120 may be formed in the gate trench 115 so as to have a substantially conformal thickness. Subsequently, the word line WL may be formed to fill at least a portion of the gate trench 115. An upper surface of the word line WL may be recessed such that a vertical level of the recessed upper surface thereof is lower than a vertical level of the upper surface of the active area ACT. The gate capping film 125 may be formed on the word line WL by depositing an insulating layer on the substrate 101 to fill the gate trench 115 and etching an upper surface thereof.

An insulating layer and a conductive layer may be sequentially formed on the entire surface of the substrate 101 and patterned to form the buffer insulating layer 128 and the first conductive pattern 141 sequentially stacked. The buffer insulating layer 128 may be made of at least one of silicon oxide, silicon nitride, and silicon oxynitride. A plurality of buffer insulating layers 128 may be formed so as to be spaced apart from each other. The first conductive pattern 141 may have a shape in a plan view corresponding to a shape in a plan view of the buffer insulating layer 128. The buffer insulating layer 128 may be formed to simultaneously cover ends of two adjacent active areas ACT, that is, the adjacent second impurity areas 105b. An upper portion of each of the element isolation layer 110, the substrate 101, and the gate capping film 125 may be etched using the buffer insulating layer 128 and the first conductive pattern 141 as an etching mask to form a bit line contact hole. The bit line contact hole may expose the first impurity area 105a.

The bit line contact pattern DC filling the bit line contact hole may be formed. The formation of the bit line contact pattern DC may include forming a conductive layer filling the bit line contact hole and performing a planarization process thereon. For example, the bit line contact pattern DC may be made of polysilicon. After the second conductive pattern 142, the third conductive pattern 143, and the first to third capping patterns 146, 147, and 148 have been sequentially formed on the first conductive pattern 141, the first to third conductive patterns 141, 142, and 143 may be sequentially etched using the first to third capping patterns 146, 147, and 148 as an etch mask. As a result, the bit line structure BLS including the bit line BL including the first to third conductive patterns 141, 142, and 143 and the bit line capping pattern BC including the first to third capping patterns 146, 147, and 147 may be formed.

The spacer structure SS may be formed on side surfaces of the bit line structure BLS. The spacer structure SS may be composed of a plurality of layers. Fence insulating patterns 154 may be formed between the spacer structures SS. The fence insulating patterns 154 may include silicon nitride or silicon oxynitride. An anisotropic etching process using the fence insulating patterns 154 and the third capping pattern 148 as an etch mask may be performed to form an opening exposing the second impurity area 105b.

The lower conductive pattern 150 may be formed in a lower portion of the opening. The lower conductive pattern 150 may be made of a semiconductor material such as polysilicon. For example, the lower conductive pattern 150 may be formed by forming a polysilicon layer filling a portion of the opening and then performing an etch-back process thereon.

The metal-semiconductor compound layer 155 may be formed on the lower conductive pattern 150. The formation of the metal-semiconductor compound layer 155 may include a deposition process and a heat treatment process of a metal layer.

The upper conductive pattern 160 may be formed in an upper portion of the opening OP. The formation of the upper conductive pattern 160 may include sequentially forming the barrier layer 162 and the conductive layer 164. Thereafter, a patterning process may be performed on the barrier layer 162 and the conductive layer 164 to form the insulating patterns 165 extending therethrough. Accordingly, the lower structure including the substrate 101, the word line structure WLS, the bit line structure BLS, etc. may be formed.

The etch stop layer 168 may be conformally formed on the lower structure LS. Mold layers 118 and preliminary supporter layers SP1′, SP2′, and SP3′ may be alternately stacked on top of each other while being disposed on the etch stop layer 168. The mold layers 118 and the preliminary supporter layers SP1′, SP2′, and SP3′ may constitute the mold structure ST. The etch stop layer 168 may include an insulating material, for example, at least one of silicon oxide, silicon nitride, silicon carbide, silicon oxycarbide, and silicon carbonitride, having an etch selectivity with respect to the mold layers 118 under a specific etching condition. The mold layers 118 may be made of silicon oxide, and the preliminary supporter layers SP1′, SP2′, and SP3′ may be made of silicon nitride.

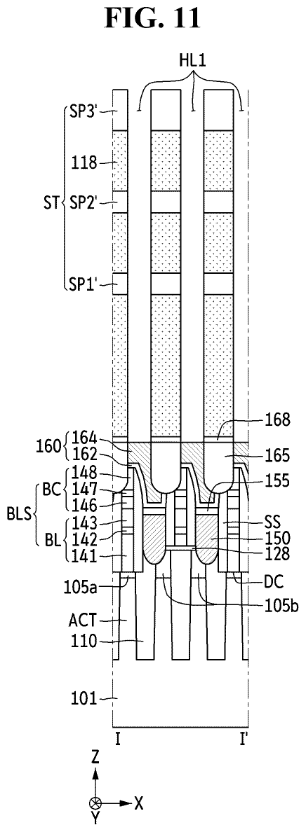

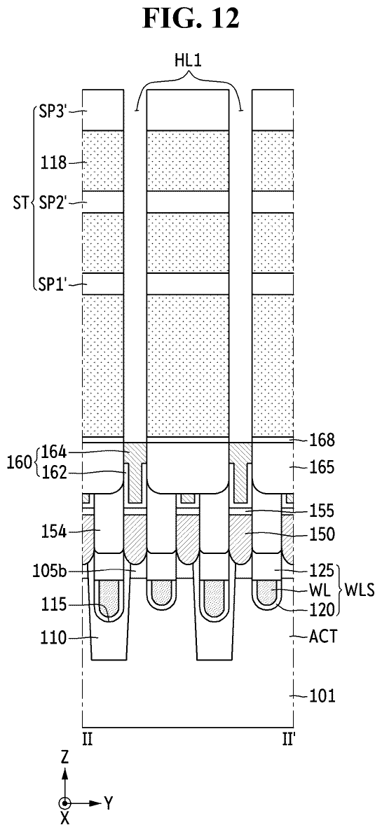

Referring to FIGS. 11 and 12, a plurality of holes HL1 may be formed to extend through the mold layers 118 and the preliminary supporter layers SP1′, SP2′, and SP3′. In the step of forming the plurality of holes HL1, the etch stop layer 168 may serve as a stopper that stops the progress of the etching process. The plurality of holes HL1 may extend through the etch stop layer 168 so as to expose the upper conductive patterns 160. The plurality of holes HL1 may be areas in which the first electrode structures 170 are to be formed. As illustrated in FIG. 1, the plurality of holes HL1 may be spaced apart from each other by a predetermined spacing and may be arranged in a regular spacing in a plan view.

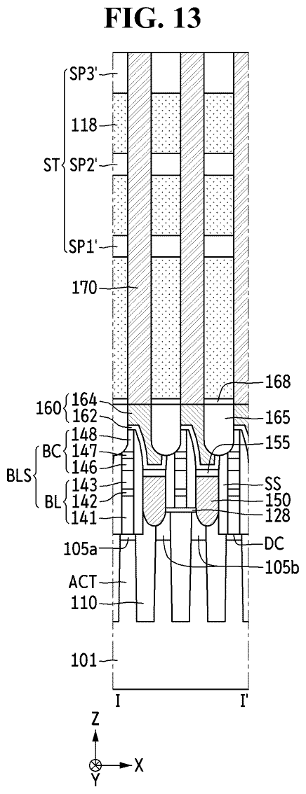

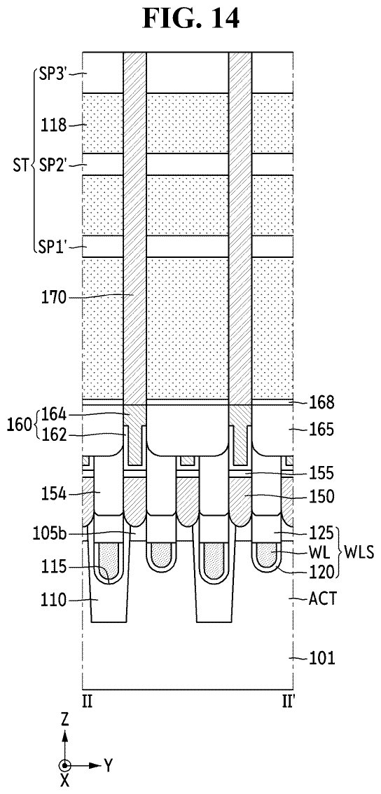

Referring to FIGS. 13 and 14, the plurality of holes HL1 may be filled with a conductive material to form the first electrode structures 170.

The first electrode structures 170 may be formed to be connected to the upper conductive pattern 160 at lower ends of the plurality of holes HL1. The formation of the first electrode structures 170 may include forming a conductive material layer in the plurality of holes HL1 and on the plurality of holes HL1, and performing a planarization process, for example, a CMP (Chemical Mechanical Polishing) process and/or an etch-back process, on the conductive material layer. Accordingly, the first electrode structures 170 may be composed of a plurality of patterns spaced apart from each other in a node isolation manner. The first electrode structures 170 may be made of, for example, at least one of polycrystalline silicon (Si), TiN, NbN, WN, VN, MoN, TaN, TiSiN, and TiCN. In some embodiments, the process of forming the first electrode structures 170 may be performed using atomic layer deposition (ALD), chemical vapor deposition (CVD), or the like.

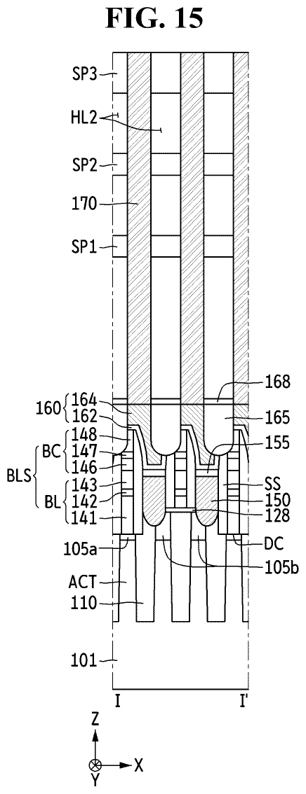

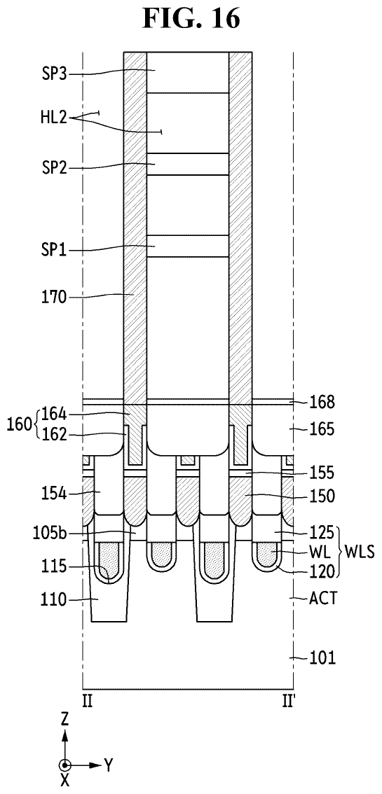

Referring to FIGS. 15 and 16, openings HL2 may be formed by removing a portion of the mold structure ST, that is, at least portions of the mold layers (118 of FIGS. 13 and 14) and/or the preliminary supporter layers (SP1′, SP2′, and SP3′ of FIGS. 13 and 14).

Thereafter, a separate mask may be formed on the first electrode structures 170, and at least portions of the mold layers (118 of FIGS. 13 and 14) and/or the preliminary supporter layers (SP1′, SP2′, and SP3′ of FIGS. 13 and 14) may be removed using the mask. Accordingly, the preliminary supporter layers SP1′, SP2′, and SP3′ of FIGS. 13 and 14 may be converted into the first to third supporter layers SP1, SP2, and SP3. The first to third supporter layers SP1, SP2, and SP3 may be patterned according to a structure of the mask so as to have a plurality of openings. As illustrated in FIG. 1, the plurality of openings may be disposed between four adjacent first electrode structures 170. The first to third supporter layers SP1, SP2, and SP3 may connect adjacent first electrode structures 170 to each other. The mold layers 118 may be selectively removed with respect to the supporter layers SP1, SP2, and SP3. In some embodiments, the process of removing the mold layers 118 may be performed in a wet etching process using an etchant (e.g., hydrogen fluoride (HF) solution). The mask may be removed after the mold layers 118 are etched, or while the mold layers 118 are etched. The openings HL2 may be formed in areas from which the mold layers 118 have been removed.

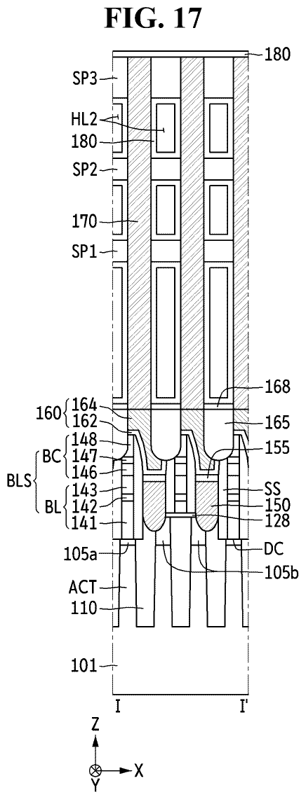

Referring to FIGS. 17 to 19, the dielectric film structure 180 and the second electrode structure 190 covering the first electrode structures 170 may be formed in the openings HL2.

The dielectric film structure 180 may be formed on the first electrode structures 170 and the first to third supporter layers SP1, SP2, and SP3.

The dielectric film structure 180 may include the first inserted insulating film 181a, the first interfacial insulating film 182a, the dielectric film 183, the second interfacial insulating film 182b, and the second inserted insulating film 181b, which are sequentially stacked.

The first inserted insulating film 181a may be formed on the first electrode structure 170 and the supporter layers SP1, SP2, and SP3. Although not shown in detail, the first inserted insulating film 181a may extend to cover the upper surface of the etch stop layer 168. Thereafter, the first interfacial insulating film 182a may be formed on the first inserted insulating film 181a, and then, the dielectric film 183 may be formed on the first interfacial insulating film 182a.

The second interfacial insulating film 182b may be formed on the dielectric film 183, and then, the second inserted insulating film 181b may be formed on the second interfacial insulating film 182b. The first inserted insulating film 181a, the first interfacial insulating film 182a, the dielectric film 183, the second interfacial insulating film 182b, and the second inserted insulating film 181b may be formed along surfaces of the first electrode structure 170, the supporter layers SP1, SP2, and SP3, and the etch stop layer 168.

A process of forming each of the first inserted insulating film 181a, the first interfacial insulating film 182a, the dielectric film 183, the second interfacial insulating film 182b, and the second inserted insulating film 181b may be performed using atomic layer deposition (ALD), chemical vapor deposition (CVD), or the like.

Thereafter, the second electrode structure 190 covering the dielectric film structure 180 may be formed. After the second inserted insulating film 181b has been formed, the second electrode structure 190 may be formed on the second inserted insulating film 181b. The process of forming the second electrode structure 190 may be performed using atomic layer deposition (ALD), chemical vapor deposition (CVD), physical vapor deposition (PVD), or the like.

Accordingly, the information storage structure CAP including the first electrode structures 170, the dielectric film structure 180, and the second electrode structure 190 may be formed. Accordingly, the semiconductor device 100 including the information storage structure CAP as illustrated in FIGS. 2 and 3 may be manufactured.

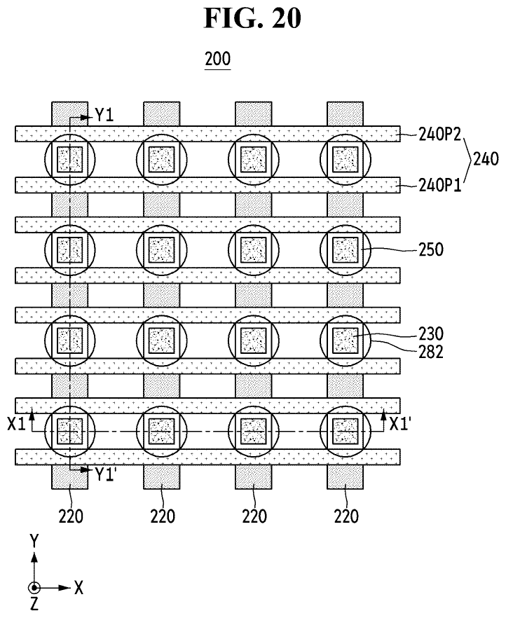

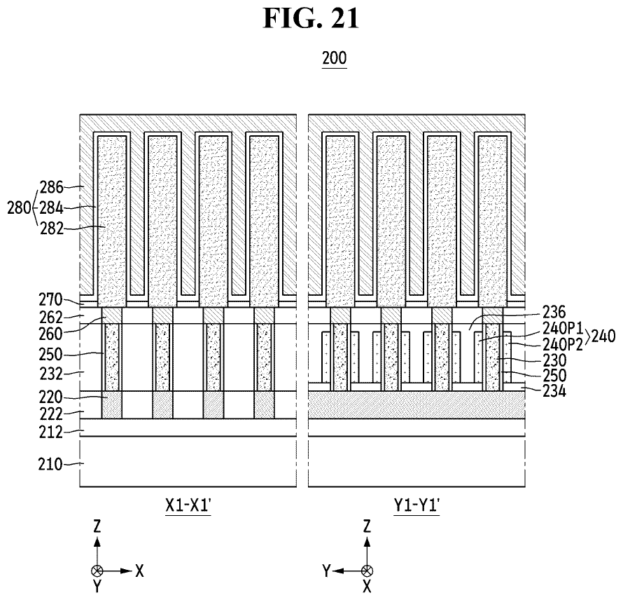

FIG. 20 is a schematic layout diagram for illustrating a semiconductor device according to some embodiments. FIG. 21 is a cross-sectional view taken along lines X1-X1′ and Y1-Y1′ of FIG. 20.

Referring to FIGS. 20 and 21, a semiconductor device 200 may include a substrate 210, a plurality of first conductive lines 220, a channel layer 230, a gate electrode 240, a gate insulating layer 250, and an information storage structure 280. The integrated circuit device 200 may be a memory device including a vertical channel transistor (VCT). The vertical channel transistor may indicate a structure in which a channel length of the channel layer 230 extends from the substrate 210 in a vertical direction.

A lower insulating layer 212 may be disposed on the substrate 210. The plurality of first conductive lines 220 may be disposed on the lower insulating layer 212, may be spaced apart from each other in the first direction X, and may extend in the second direction Y. A plurality of first insulating patterns 222 may be disposed on the lower insulating layer 212 so as to fill a space between adjacent ones of the plurality of first conductive lines 220. The plurality of first insulating patterns 222 may extend in the second direction Y, and an upper surface of each of the plurality of first insulating patterns 222 may be disposed at the same vertical level as a vertical level of an upper surface of each of the plurality of first conductive lines 220. The plurality of first conductive lines 220 may function as bit lines of the semiconductor device 200.

In some embodiments, each of the plurality of first conductive lines 220 may include doped polysilicon, a metal, a conductive metal nitride, a conductive metal silicide, a conductive metal oxide, or a combination thereof. For example, each of the plurality of first conductive lines 220 may include doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ RuOₓ, or a combination thereof. However, embodiments of the present disclosure are not limited thereto. Each of the plurality of first conductive lines 220 may include a single layer or multiple layers made of the above-described materials. In some embodiments, each of the plurality of first conductive lines 220 may include a two-dimensional semiconductor material. For example, the two-dimensional semiconductor material may include graphene, carbon nanotubes, or a combination thereof.

The channel layers 230 may be disposed on the plurality of first conductive lines 220 and may be arranged in a matrix form so as to be spaced apart from each other in the first direction X and the second direction Y. The channel layer 230 may have a first width in the first direction X and a first vertical dimension in the third direction Z, and the first vertical dimension may be greater than the first width. For example, the first vertical dimension may be in a range of about 2 to 10 times of the first width. However, embodiments of the present disclosure are not limited thereto. A bottom portion of the channel layer 230 may function as a first source/drain area (not shown), an upper portion of the channel layer 230 may function as a second source/drain area (not shown), and a portion of the channel layer 230 between the first and second source/drain areas may function as a channel area (not shown). The first source/drain area and the second source/drain area may be vertically spaced apart from each other, and the channel area may be a vertical channel area.

In some embodiments, the channel layer 230 may include an oxide semiconductor. For example, the oxide semiconductor may include InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O or combinations thereof. The channel layer 230 may include a single layer or multiple layers made of the oxide semiconductor. In some embodiments, the channel layer 230 may have a bandgap energy greater than that of silicon. For example, the channel layer 230 may have a bandgap energy of about 1.5 eV to about 5.6 eV. For example, the channel layer 230 may have optimal channel performance when it has a bandgap energy of about 2.0 eV to 4.0 eV. For example, the channel layer 230 may be made of polycrystalline or amorphous. However, the present disclosure is not limited thereto. In some embodiments, the channel layer 230 may be polycrystalline or amorphous. However, embodiments of the present disclosure are not limited thereto. In some embodiments, the channel layer 230 may include a two-dimensional semiconductor material, and for example, the two-dimensional semiconductor material may include graphene, carbon nanotubes, or a combination thereof.

The gate electrode 240 may extend in the first direction DR1 and may be disposed on both opposing sidewalls of the channel layer 230. The gate electrode 240 may include a first sub-gate electrode 240P1 facing a first sidewall of the channel layer 230 and a second sub-gate electrode 240P2 facing a second sidewall opposite the first sidewall of the channel layer 230. As one channel layer 230 is disposed between the first sub-gate electrode 240P1 and the second sub-gate electrode 240P2, the semiconductor device may have a dual gate transistor structure. However, the technical idea of the present disclosure is not limited thereto, and the second sub-gate electrode 240P2 may be omitted and only the first sub-gate electrode 240P1 facing the first sidewall of the channel layer 230 may be formed to achieve a single gate transistor structure.

The gate electrode 240 may include doped polysilicon, metal, conductive metal nitride, conductive metal silicide, conductive metal oxide, or a combination thereof. For example, the gate electrode 240 may be made of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, or a combination thereof. However, embodiments of the present disclosure are not limited thereto.

The gate insulating layer 250 may surround a sidewall of the channel layer 230 and may be interposed between the channel layer 230 and the gate electrode 240. For example, as illustrated in FIG. 21, an entirety of the sidewall of the channel layer 230 may be surrounded with the gate insulating layer 250, and a portion of a sidewall of the gate electrode 240 may be in contact with the gate insulating layer 250. In some further embodiments, the gate insulating layer 250 may extend in an extension direction (i.e., the first direction X) of the gate electrode 240, and only two sidewalls facing the gate electrode 240 among the sidewalls of the channel layer 230 may contact the gate insulating layer 250.

In some embodiments, the gate insulating layer 250 may include a silicon oxide film, a silicon oxynitride film, a high-k dielectric film having a higher dielectric constant than that of the silicon oxide film, or a combination thereof. The high-k dielectric film may be made of a metal oxide or a metal oxynitride. For example, the high-k dielectric film acting as the gate insulating layer 250 may be made of HfO₂, HfSiO, HfSiON, HfTaO, HfTiO, HfZrO, ZrO₂, Al₂O₃, or a combination thereof. However, embodiments of the present disclosure are not limited thereto.

A plurality of second insulating patterns 232 may extend in the second direction Y while being disposed on the plurality of first insulating patterns 222. The channel layer 230 may be disposed between two adjacent second insulating patterns 232 among the plurality of second insulating patterns 232. In addition, between two adjacent second insulating patterns 232, a first buried layer 234 and a second buried layer 236 may be disposed in a space between two adjacent channel layers 230. The first buried layer 234 may be disposed in a bottom portion of a space between two adjacent channel layers 230, and the second buried layer 236 may be formed on the first buried layer 234 so as to fill the rest of the space between the two adjacent channel layers 230. An upper surface of the second buried layer 236 may be disposed at the same vertical level as a vertical level of an upper surface of the channel layer 230, and the second buried layer 236 may cover an upper surface of the gate electrode 240. Alternatively, each of the plurality of second insulating patterns 232 and each of the plurality of first insulating patterns 222 may be monolithic, or the second buried layer 236 and the first buried layer 234 may be monolithic.

A storage contact 260 may be disposed on the channel layer 230. The storage contact 260 may be disposed to vertically overlap the channel layer 230. The storage contacts 260 may be arranged in a matrix form and may be spaced apart from each other in the first direction X and the second direction Y. The storage contact 260 may include doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, or a combination thereof. However, embodiments of the present disclosure are not limited thereto. An upper insulating layer 262 may surround a sidewall of the storage contact 260 while being disposed on the plurality of second insulating patterns 232 and the second buried layer 236.

An etch stop film 270 may be disposed on the upper insulating layer 262, and the information storage structure 280 may be disposed on the etch stop film 270. The information storage structure 280 may include a first electrode structure 282, a dielectric film 284, and a plate electrode 286.

The first electrode structure 282 may extend through the etch stop film 270 so as to be electrically connected to an upper surface of the storage contact 260. The first electrode structure 282 may be formed in a pillar shape extending in the third direction Z. However, embodiments of the present disclosure are not limited thereto. In some embodiments, the first electrode structure 282 may be disposed to vertically overlap the storage contact 260. The first electrode structures 282 may be arranged in a matrix form and may be spaced apart from each other in the first direction X and the second direction Y. Alternatively, a landing pad (not shown) may be further disposed between the storage contact 260 and the first electrode structure 282 so that the first electrode structures 282 may be arranged in a hexagonal shape.

In the semiconductor device 200, the first electrode structure 282 of the information storage structure 280 may be the first electrode structure 170 as described with reference to FIGS. 1 to 19. The plate electrode 286 of the information storage structure 280 may be the second electrode structure 190 as described with reference to FIGS. 1 to 19.

In the semiconductor device 200, the dielectric film 284 of the information storage structure 280 may include the first inserted insulating film 181a, the first interfacial insulating film 182a, the dielectric film 183, the second interfacial insulating film 182b, and the second inserted insulating film 181b as described above with reference to FIGS. 1 to 19.

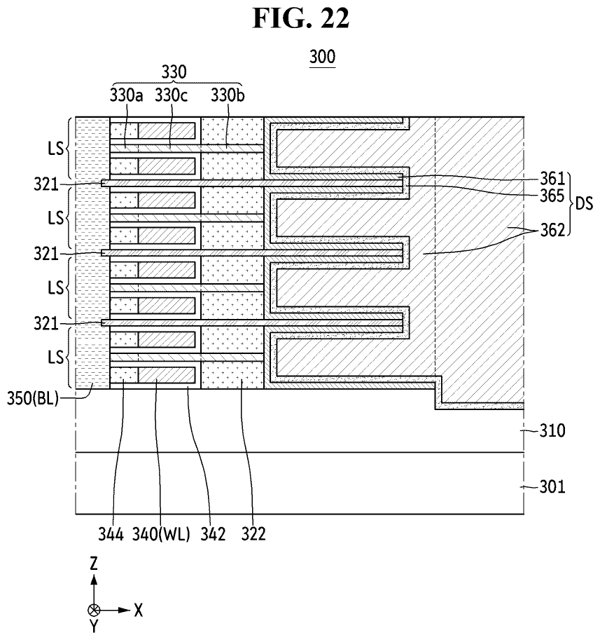

FIG. 22 is a cross-sectional view of a semiconductor device according to some embodiments.

Referring to FIG. 22, a semiconductor device 300 may include a substrate 301, a lower structure 310 disposed on the substrate 301, a plurality of structures LS and a plurality of first insulating layers 321 alternately stacked on top of each other while being disposed on the substrate 301, and a second conductive pattern 350.

Each of the plurality of structures LS may include an active layer 330 extending in the first direction X, a first conductive pattern 340 intersecting the active layer 330 and extending in the second direction Y perpendicular to the first direction X, a gate dielectric layer 342 between the active layer 330 and the first conductive pattern 340, a gate capping layer 344 between the first conductive pattern 340 and the second conductive pattern 350, a first electrode 361 of the information storage structure DS, and a second insulating layer 32 between the first conductive pattern 340 and the first electrode 361.

The information storage structure DS may further include a dielectric layer 365 disposed on the first electrode 361, and a second electrode 362 disposed on the dielectric film 365.

In the semiconductor device 300, the first electrode 361 of the information storage structure DS may be the first electrode structure 170 as described with reference to FIGS. 1 to 19. The second electrode 362 of the information storage structure 280 may be the second electrode structure 190 as described with reference to FIGS. 1 to 19.

In the semiconductor device 300, the dielectric film 365 of the information storage structure DS may include the first inserted insulating film 181a, the first interfacial insulating film 182a, the dielectric film 183, the second interfacial insulating film 182b, and the second inserted insulating film 181b as described above with reference to FIGS. 1 to 19.

The first direction X and the second direction Y may be perpendicular to each other and may be parallel to an upper surface of the substrate 301. The third direction Z may be perpendicular to the first direction X and the second direction Y and may be perpendicular to the upper surface of the substrate 301.

The lower structure 310 may be disposed on the substrate 301. The plurality of structures LS and the plurality of first insulating layers 321 may be alternately stacked on top of each other while being disposed on the lower structure 310. The lower structure 310 may include an element area DR on the substrate 301 and an insulating area IR covering the element area DR. The insulating area may include insulating layers made of an insulating material, for example, at least one of silicon oxide, silicon nitride, silicon oxynitride, and silicon oxycarbide.

The plurality of structures LS and the plurality of first insulating layers 321 may constitute a mold structure on the substrate 301. Each of the plurality of structures LS may be disposed between adjacent ones of the plurality of first insulating layers 321, and the plurality of structures LS may be spaced apart from each other in the third direction Z via each of the plurality of first insulating layers 321. The first insulating layer 321 may extend in the first direction X, and an end thereof may extend into the second conductive pattern 350. The second insulating layer 322 may be disposed between the first insulating layer 321 and the active layer 330 and between the first conductive pattern 340 and the information storage structure DS. Each of the first insulating layer 321 and the second insulating layer 322 may include an insulating material, for example, at least one of silicon oxide, silicon nitride, silicon oxynitride, and silicon oxycarbide. The first insulating layer 321 may extend horizontally in a length by larger than an extension length of the second insulating layer 322. A thickness of the second insulating layer 322 may be greater than a thickness of the first insulating layer 321.

The active layer 330 may be disposed on the substrate 301 and may horizontally extend in the first direction X. A plurality of active layers 330 may be stacked so as to be spaced apart from each other in the third direction Z. The plurality of active layers 330 may be arranged in the second direction Y. Each of the plurality of active layers 330 arranged in the third direction Z may be disposed between adjacent ones of the plurality of first insulating layers 321. The active layer 330 may have a linear shape, a bar shape, or a pillar shape that interests the first conductive pattern 340 and extends in the first direction X. The active layer 330 may include a semiconductor material, for example, silicon, germanium, or silicon-germanium.

The active layer 330 may include a first impurity area 330a, a second impurity area 330b, and a channel area 330c. The first impurity area 330a may be electrically connected to the second conductive pattern 350. The second impurity area 330b may be electrically connected to the first electrode 361 of the information storage structure DS. A length of the second impurity area 330b in the first direction X may be greater than a length of the first impurity area 330a in the first direction X. However, embodiments of the present disclosure are not limited thereto. The channel area 330c may be disposed between the first impurity area 330a and the second impurity area 330b. The channel area 330c may overlap the first conductive pattern 340. The first impurity area 330a and the second impurity area 330b may be spaced apart from each other in the horizontal direction and may be disposed at the same level, and the channel area 330c may be a horizontal channel area 330c.

Each of the first impurity area 330a and the second impurity area 330b may be formed by doping or ion implantation of impurities into the active layer 330. Each of the first impurity area 330a and the second impurity area 330b may have n-type or p-type conductivity.

A portion of the first impurity area 330a may correspond to a source area of the transistor, a portion of the second impurity area 330b may correspond to a drain area of the transistor, and the channel area 330c may correspond to a channel of the transistor. A portion of the first impurity area 330a may provide a first contact area for directly connecting the source area of the transistor to the second conductive pattern 350, that is, the bit line BL, and a portion of the second impurity area 330b may provide a second contact area for directly connecting the drain area of the transistor to the information storage structure DS.

In another example, the active layer 330 may include an oxide semiconductor, for example, at least one of hafnium-silicon oxide (HSO), hafnium-zinc oxide (HZO), indium-zinc oxide (IZO), indium-gallium oxide (IGO), indium-tin oxide (ITO), indium-gallium-zinc oxide (IGZO), and indium-tin-zinc oxide (ITZO).

In still another example, the active layer 330 may include a two-dimensional material (2D material) in which atoms may form a predetermined crystal structure to constitute a channel of a transistor. The 2D material layer included in the active layer 330 may include at least one of a transition metal dichalcogenide (TMD) material layer, a black phosphorous material layer, and a hexagonal boron-nitride (nBN) material layer. For example, the two-dimensional material layer included in the active layer 330 may include at least one of BiOSe, Crl, WSe₂, MoS₂, TaS, WS, SnSe, ReS, β-SnTe, MnO, AsS, P (black), InSe, h-BN, GaSe, GaN, SrTiO, MXene, and Janus 2D materials, which may constitute a two-dimensional material layer.

The first conductive pattern 340 may be disposed on the substrate 301 and may horizontally extend in the second direction Y. A plurality of first conductive patterns 340 may be arranged so as to be spaced apart from each other in the third direction Z, and may be arranged in the first direction X. The first conductive pattern 340 may be disposed between the channel area 330c of the active layer 330 and the first insulating layer 321. The first conductive pattern 340 may be disposed on an upper surface and a lower surface of the active layer 330. The first conductive pattern 340 may have a linear shape, a bar shape, or a pillar shape that intersects the second conductive pattern 350 and extends in the second direction Y. Although not shown, the plurality of first conductive patterns 340 arranged in the third direction Z in one memory cell may extend by different lengths in the second direction Y such that each of the plurality of first conductive patterns 340 provides a contact area as an exposed upper surface of each of the plurality of first conductive patterns.

The first conductive pattern 340 may include a conductive material, and the conductive material may include at least one of a doped semiconductor material, a conductive metal nitride, a metal, and a metal-semiconductor compound. The first conductive pattern 340 may be a word line WL and may be referred to as a “gate electrode”.

The gate dielectric layer 342 may be disposed between the first conductive pattern 340 and the active layer 330. The gate insulating pattern 342 may be formed in an inner space of a gap area formed by etching the second insulating layer 322 inwardly from a side surface thereof in an area between adjacent first insulating layers 321 and may be formed so as to have a substantially conformal thickness. The gate insulating pattern 342 may include silicon oxide, silicon nitride, or a high-k material.

The gate capping layer 344 may be disposed to fill a space obtained by removing a portion of the first conductive pattern 340 inwardly from the side surface thereof. For example, a side surface of the gate capping layer 344 may be in contact with a side surface of the first conductive pattern 340, and an upper surface and a lower surface thereof may be covered with the gate insulating pattern 342. The gate capping layer 344 may electrically insulate the first conductive pattern 340 from the second conductive pattern 350.

The second conductive pattern 350 may vertically extend in the third direction Z while being disposed on the substrate 301. A plurality of second conductive patterns 350 may be arranged in the second direction Y. The second conductive pattern 350 may be disposed adjacent to the first impurity area 330a and a first end surface of the active layer 330. A plurality of active layers 330 stacked in the third direction Z may be electrically connected to one second conductive pattern 350. The second conductive pattern 350 may have a linear shape, a bar shape, or a pillar shape extending in the third direction Z. Although not shown, the semiconductor device may further include an upper wiring disposed on the second conductive pattern 350, connected to the second conductive pattern 350, and extending in the first direction X. The second conductive pattern 350 may include at least one of a doped semiconductor material, a conductive metal nitride, a metal, and a metal-semiconductor compound.

The information storage structure DS may be disposed adjacent to the second impurity area 330b and a second end surface of the active layer 330. The information storage structure DS may be electrically connected to the active layer 330. The information storage structure DS may include the first electrode 361, the dielectric film 365 on the first electrode 361, and the second electrode 362 on the dielectric film 365. The first electrode 361 of the information storage structure DS may have a cylindrical shape. However, embodiments of the present disclosure are not limited thereto, and the first electrode 361 of the information storage structure DS may have a pillar shape in some embodiments.

The first electrode 361 may be formed in an inner space of a gap area formed by etching the second insulating layer 322 inwardly from a side surface thereof and may be formed so as to have a substantially conformal thickness. The first electrode 361 may be in a state in which respective nodes of the structures LS are isolated from each other by depositing a conductive material and then removing a portion on a side surface of the first insulating layer 321. The first electrode 361 may include at least one of a doped semiconductor material, a conductive metal nitride, a metal, and a conductive metal oxide.

The dielectric layer 365 may conformally cover the first electrode 361. The dielectric layer 365 may cover a protruding portion of the first electrode 361 and may include a portion protruding toward the second electrode 362. The dielectric layer 365 may include a high-k material, silicon oxide, silicon nitride, silicon oxynitride, or a combination thereof. However, according to embodiments, the dielectric film 365 may include oxide, nitride, silicide, oxynitride, or silicon oxynitride including at least one of Hf, Al, Zr, and La.

The second electrode 362 may cover the dielectric film 365. The second electrode 362 may fill an inner space of the first electrode 361 having a cylindrical shape. The second electrode 362 may include at least one of a doped semiconductor material, a conductive metal nitride, a metal, and a metal-semiconductor compound.

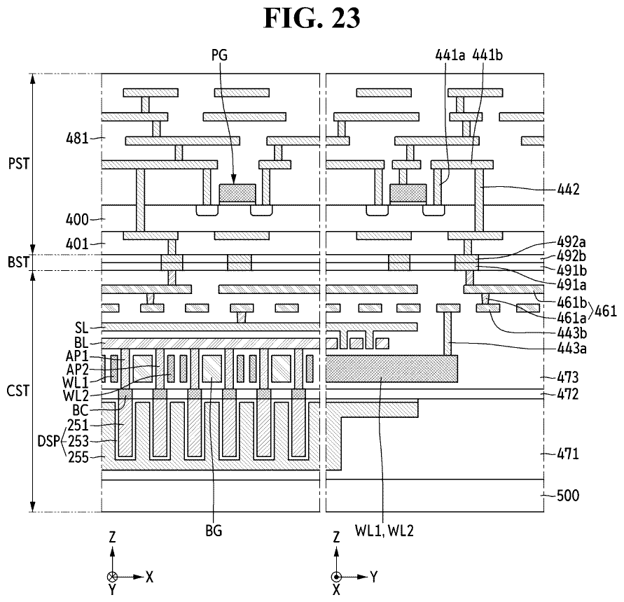

FIG. 23 is an example diagram for illustrating a semiconductor device according to some embodiments. For convenience of description, contents duplicate with those as above-described using FIGS. 1 to 22 will be briefly described or descriptions thereof will be omitted.

Referring to FIG. 23, the semiconductor device according to some embodiments may include a cell structure CST, a peripheral structure PST, and a bonding structure BST between the cell structure CST and the peripheral structure PST, and may include word lines WL1 and WL2 extending in the second direction Y, a bit line BL extending in the first direction X intersecting the second direction Y, and active patterns AP1 and AP2 connected to the bit line BL. The peripheral structure PST may be disposed on the cell structure CST in a direction parallel to the third direction Z.

The cell structure CST may include the word lines WL1 and WL2, the bit line BL, the active patterns AP1 and AP2, a back gate electrode BG, a data storage pattern DSP, etc. The peripheral structure PST may include a peripheral active substrate 400, a peripheral gate structure PG, etc.

The substrate 500 may be a silicon substrate, or may include a material other than silicon, for example, silicon germanium, indium antimonide, a lead telluride compound, indium arsenide, indium phosphide, gallium arsenide, or gallium antimonide. However, embodiments of the present disclosure are not limited thereto.

The data storage pattern DSP may be disposed on the substrate 500. Although not shown, the data storage patterns DSP may be arranged in a matrix form along the first direction X and the second direction Y.

For example, the third direction Z may be a thickness direction of the substrate 500. The first direction X and the second direction Y may be parallel to the upper surface of the substrate 500.

In one example, the data storage patterns DSP may be capacitors. Each of the data storage patterns DSP may include a storage electrode 451, a plate electrode 455, and a capacitor dielectric film 453 interposed between the storage electrode 451 and the plate electrode 455. In a plan view, the storage electrode 451 may have various shapes such as a circle, an oval, a rectangle, a square, a rhombus, and a hexagon.

Each of the storage electrode 451 and the plate electrode 455 may include, for example, at least one of a conductive semiconductor material, a conductive metal nitride, a conductive metal silicon nitride, a metal carbonitride, a conductive metal silicide, a conductive metal oxide, and a metal. The capacitor dielectric film 453 may include at least one of a ferroelectric material, an anti-ferroelectric material, and a paraelectric material. For example, the capacitor dielectric film 453 may include one of a ferroelectric material, an anti-ferroelectric material, a paraelectric material, a combination of a ferroelectric material and an anti-ferroelectric material, a combination of a ferroelectric material and a paraelectric material, a combination of a paraelectric material and an anti-ferroelectric material, a combination of a ferroelectric material, an anti-ferroelectric material, and a paraelectric material.

Alternatively, the data storage patterns DSP may be variable resistance patterns that may be switched to two resistance states by an electrical pulse applied to a memory element. For example, the data storage patterns DSP may include a phase-change material whose a crystal state changes depending on an amount of current, perovskite compounds, a transition metal oxide, magnetic materials, ferromagnetic materials, or antiferromagnetic materials.

Contact patterns BC may be disposed on the storage electrode 451. The contact patterns BC may be connected to a first active pattern AP1 and a second active pattern AP2, respectively. Each of the contact patterns BC may have various shapes such as a circle, an oval, a rectangle, a square, a rhombus, a hexagon, and the like, in a plan view.

The contact pattern BC may include a conductive material. The contact pattern BC may include, for example, at least one of doped polysilicon, conductive metal nitride, conductive metal silicon nitride, metal carbonitride, conductive metal silicide, conductive metal oxide, a two-dimensional material, and a metal.

The first active patterns AP1 and the second active patterns AP2 may be disposed on the data storage pattern DSP. The data storage patterns DSP may be disposed between the first active pattern AP1 and the substrate 500. The data storage patterns DSP may be disposed between the second active pattern AP1 and the substrate 500. The first active patterns AP1 and the second active patterns AP 2 may be alternately arranged along the first direction X. Although not shown, the first and second active patterns AP1 and AP2 may be two-dimensionally arranged along the first direction X and the second direction Y.

For example, each of the first active pattern AP1 and the second active pattern AP2 may be made of a single crystal semiconductor material. In one example, each of the first active pattern AP1 and the second active pattern AP2 may be made of single crystalline silicon.

A back gate electrode BG may be disposed on the data storage pattern DSP. The back gate electrode BG may be disposed on the contact pattern BC. The back gate electrode BG may extend in the second direction Y. The back gate electrodes BG may be spaced apart from each other in the first direction X. The back gate electrodes BG may be spaced apart from each other by a predetermined distance.

Each back gate electrode BG may be disposed between the first active pattern AP1 and the second active pattern AP2 adjacent to each other in the first direction X. In other words, the first active pattern AP1 may be disposed on one side of each back gate electrode BG, and the second active pattern AP2 may be disposed on the other side of each back gate electrode BG.

The first active pattern AP1 may be disposed between a first word line WL1 and the back gate electrode BG. The second active pattern AP2 may be disposed between a second word line WL2 and the back gate electrode BG. A pair of the first word line WL1 and the second word line WL2 may be disposed between the back gate electrodes BG adjacent to each other in the first direction X.

The back gate electrode BG may include a conductive material, and for example, may include at least one of doped polysilicon, conductive metal nitride, conductive metal silicon nitride, metal carbonitride, conductive metal silicide, conductive metal oxide, two-dimensional material, and metal.

Although not shown, a back gate insulating film may be disposed between the back gate electrode BG and the first active pattern AP1 and between the back gate electrode BG and the second active pattern AP2.

The first word line WL1 and the second word line WL2 may be disposed on the data storage pattern DSP. The first word line WL1 and the second word line WL2 may be disposed on the contact patterns BC. The data storage patterns DSP may be disposed between the first word line WL1 and the substrate 500. The data storage patterns DSP may be disposed between the second word line WL2 and the substrate 500.

Each of the first word line WL1 and the second word line WL2 may extend in the second direction Y. The first word lines WL1 and the second word lines WL2 may be alternately arranged with each other in the first direction X.

The first word line WL1 and the second word line WL2 may be spaced apart from the bit line BL and the contact pattern BC in the third direction Z. The first word line WL1 and the second word line WL2 may be located between the bit line BL and the contact pattern BC.

Each of the first word line WL1 and the second word line WL2 may include a conductive material. Each of the first word line WL1 and the second word line WL2 may include, for example, at least one of doped polysilicon, conductive metal nitride, conductive metal silicon nitride, metal carbonitride, conductive metal silicide, conductive metal oxide, two-dimensional material, and metal.

Although not shown, a gate insulating film may be disposed between the first word line WL1 and the first active pattern AP1 and between the second word line WL2 and the second active pattern AP2.

The bit line BL may be disposed on the first active pattern AP1 and the second active pattern AP2. The bit line BL may be connected to the first active pattern AP1 and the second active pattern AP2.

The bit line BL may be disposed on the back gate electrode BG, the first word line WL1, and the second word line WL2. The bit line BL may extend in the first direction X and across the back gate electrode BG.

The bit line BL may include a conductive material, and may include, for example, at least one of doped polysilicon, conductive metal nitride, conductive metal silicon nitride, metal carbonitride, conductive metal silicide, conductive metal oxide, two-dimensional material, and metal.

A shielding conductive pattern SL may be disposed on the bit line BL. The bit line BL may be disposed between the shielding conductive pattern SL and the first word line WL1. The bit line BL may be disposed between the shielding conductive pattern SL and the second word line WL2.

For example, the shielding conductive pattern SL may include a shielding conductive plate and a plurality of shielding conductive protrusions. The shielding conductive plate may have a flat plate shape. The plurality of shielding conductive protrusions may protrude from the shielding conductive plate in the third direction Z. The shielding conductive protrusion may be disposed between the bit lines BL adjacent to each other in the second direction Y.

The shielding conductive pattern SL may include a conductive material, and for example, may include at least one of a conductive metal nitride, a conductive metal silicon nitride, a metal carbonitride, a conductive metal silicide, a conductive metal oxide, a two-dimensional material, and a metal.

Unlike what is shown, the shielding conductive pattern SL may not include the flat plate-shaped shielding conductive plate. In this case, the shielding conductive pattern SL may include a plurality of shielding conductive protrusions having a line shape.

The data storage pattern DSP is illustrated as being disposed between the substrate 500 and the bit line BL. However, embodiments of the present disclosure are not limited thereto. In the semiconductor device according to some embodiments, the bit line BL, the first word line WL1, and the second word line WL2 may be disposed between the substrate 500 and the peripheral active substrate 400.

A first lower insulating film 471, a second lower insulating film 472, and a third lower insulating film 473 may be sequentially disposed on the substrate 500. The data storage pattern DSP may be disposed in the first lower insulating film 471. The contact pattern BC may be disposed in the second lower insulating film 472. The first and second word lines WL1 and WL2, the bit line BL, and the shielding conductive pattern SL may be disposed in the third lower insulating film 473.

Each of the first lower insulating film 471, the second lower insulating film 472, and the third lower insulating film 473 may include an insulating material. Although each of the first lower insulating film 471, the second lower insulating film 472, and the third lower insulating film 473 is illustrated as being embodied as a single film, this is only for convenience of illustration, and embodiments of the present disclosure are not limited thereto.

A lower contact plug 443a and a lower wiring line 443b may be disposed in the third lower insulating film 473. The lower wiring line 443b may be disposed on the data storage pattern DSP, the bit line BL, the first word line WL1, and the second word line WL2.

The lower contact plug 443a may connect the lower wiring line 443b and the word line WL1 and WL2 to each other. The lower contact plug 443a may connect the lower wiring line 443b and the shielding conductive pattern SL to each other. Although not shown, the lower contact plug 443a may connect the lower wiring line 443b and the bit line BL to each other. In addition, the lower contact plug 443a may connect the lower wiring line 443b and the plate electrode 455 of the data storage pattern DSP to each other.

It is illustrated that the lower contact plug 443a and the lower wiring line 443b are different films. However, embodiments of the present disclosure are not limited thereto. A boundary between the lower contact plug 443a and the lower wiring line 443b may not be defined. Each of the lower contact plug 443a and the lower wiring line 443b includes a conductive material.

A first connection wiring structure 461 may be disposed on the lower wiring line 443b. The first connection wiring structure 461 may be connected to the lower wiring line 443b. The first connection wiring structure 461 may be disposed in the third lower insulating film 473.

The first connection wiring structure 461 may include a first connection wiring 461b and a first connection via 461a. Although the first connection wiring structure 461 is illustrated as including the first connection wiring 461b disposed at one metal level, this is only for convenience of illustration, and embodiments of the present disclosure are not limited thereto. Unlike the illustrated example, the first connection wiring structure 461 may include a plurality of first connection wirings 461b respectively disposed at different metal levels.

Each of the first connection wiring 461b and the first connection via 461a may include a conductive material. Although the first connection wiring 461b and the first connection via 461a are illustrated as being different films, embodiments of the present disclosure are not limited thereto.

The peripheral active substrate 400 may be disposed on the first connection wiring structure 461. The peripheral active substrate 400 may be spaced apart from the substrate 500 in the third direction Z. The first connection wiring structure 461 may be disposed between the substrate 500 and the peripheral active substrate 400.

The peripheral active substrate 400 may include silicon, silicon germanium, indium antimonide, a lead telluride compound, indium arsenide, indium phosphide, gallium arsenide, or gallium antimonide. However, embodiments of the present disclosure are not limited thereto.

An interlayer insulating film 401 may be disposed under the peripheral active substrate 400. The interlayer insulating film 401 may include, for example, an insulating material such as silicon oxide and/or silicon nitride.

The peripheral gate structure PG may be disposed on the peripheral active substrate 400. The peripheral gate structure PG may be included in a sensing transistor, a transfer transistor, a driving transistor, etc. The peripheral gate structure PG may include a peripheral gate insulating film, a peripheral gate conductive film, and a peripheral source/drain area.

The upper insulating film 481 is disposed on the peripheral active substrate 400. The upper insulating film 481 may include an insulating material. Although the upper insulating film 481 is illustrated as being embodied as a single film, this is intended only for convenience of illustration, and the present disclosure is not limited thereto.

A peripheral contact plug 441a and a peripheral wiring line 441b may be disposed in the upper interlayer insulating film 481.

The peripheral contact plug 441a may be connected to the peripheral gate structure PG. For example, the peripheral contact plug 441a may be connected to the peripheral source/drain area and/or a peripheral gate conductive film.

The peripheral wiring line 441b may be disposed on the peripheral contact plug 441a and the peripheral gate structure PG. The peripheral wiring line 441b may be disposed on the peripheral active substrate 400. The peripheral wiring line 441b is connected to the peripheral contact plug 441a. For example, the peripheral wiring line 441b may be a wiring line closest to the peripheral gate structure PG in the third direction Z.

The peripheral contact plug 441a and the peripheral wiring line 441b are illustrated as different films. However, embodiments of the present disclosure are not limited thereto. A boundary between the peripheral contact plug 441a and the peripheral wiring line 441b may not be defined. Each of the peripheral contact plug 441a and the peripheral wiring line 441b includes a conductive material.

The bonding structure BST may include a first bonding pad 491a and a first bonding insulating layer 491b adjacent to the cell structure CST, and a second bonding pad 492a and a second bonding insulating layer 492b adjacent to the peripheral structure PST. The first bonding pad 491a may be disposed in the first bonding insulating layer 491b, and the second bonding pad 492a may be disposed in the second bonding insulating layer 492b.

For example, each of the first bonding pad 491a and the second bonding pad 492a may include a conductive material such as copper (Cu), and each of the first bonding insulating layer 491b and the second bonding insulating layer 492b may include an insulating material such as silicon carbonitride. However, embodiments of the present disclosure are not limited thereto.

The first bonding pad 491a may be directly bonded to the second bonding pad 492a in a Cu—Cu bonding manner. The cell structure CST and the peripheral structure PST may be bonded to each other in a hybrid bonding manner via bonding between a Cu—Cu bonding and an insulating material.

A second connection wiring structure 442 may be disposed between the peripheral wiring line 441b and the bonding structure BST. The second connection wiring structure 442 may connect the peripheral wiring line 441b and the bonding structure BST to each other. For example, the peripheral wiring line 441b may be connected to the second bonding pad 492a via the second connection wiring structure 442 and wirings in the interlayer insulating film 401. The second connection wiring structure 442 may extend in the third direction Z. The second connection wiring structure 442 includes a conductive material.

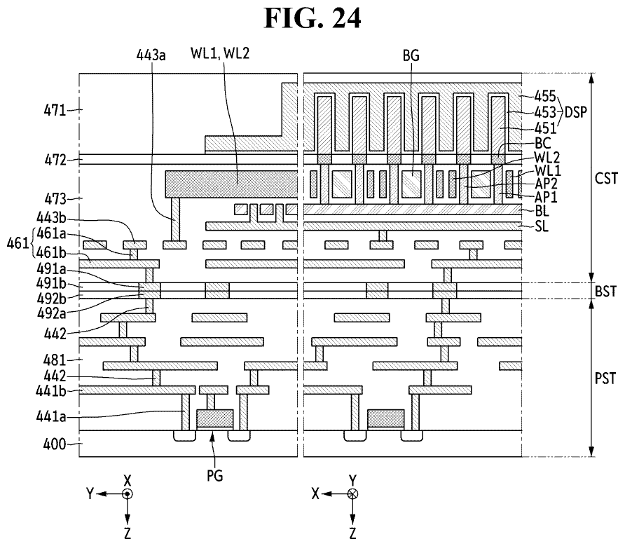

FIG. 24 is an example diagram for illustrating a semiconductor device according to some embodiments. For convenience of description, contents duplicate with those as described above with reference to FIGS. 1 to 23 will be briefly described or descriptions thereof will be omitted.

Referring to FIG. 24, the semiconductor device according to some embodiments includes a cell structure CST, a peripheral structure PST, and a bonding structure BST between the cell structure CST and the peripheral structure PST. The cell structure CST may be disposed on top of the peripheral structure PST in a direction parallel to the third direction Z. Unlike FIG. 23, the semiconductor device illustrated in FIG. 24 may not include the interlayer insulating film 401 and the substrate 500.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above are not restrictive but illustrative in all respects.

What is claimed is:

1. A capacitor structure comprising:
an electrode structure including a first electrode and a second electrode on the first electrode;
a dielectric film disposed between the first electrode and the second electrode, wherein the dielectric film includes a rutile phase material and has a first thickness;
a first interfacial insulating film disposed between the first electrode and the dielectric film and having a second thickness smaller than the first thickness; and
a first inserted insulating film disposed between the first electrode and the first interfacial insulating film and having a third thickness smaller than the second thickness.

2. The capacitor structure of claim 1, wherein the first interfacial insulating film includes a rutile phase material.

3. The capacitor structure of claim 1, wherein the first inserted insulating film is free of a rutile phase material.

4. The capacitor structure of claim 1, wherein the first interfacial insulating film includes a first metal oxide layer and a second metal oxide layer sequentially stacked on the first inserted insulating film, and
wherein the first metal oxide layer and the second metal oxide layer include different metal materials.

5. The capacitor structure of claim 1, further comprising:
a second interfacial insulating film disposed between the second electrode and the dielectric film and having a fourth thickness smaller than the first thickness; and
a second inserted insulating film disposed between the second electrode and the second interfacial insulating film and having a fifth thickness smaller than the fourth thickness.

6. The capacitor structure of claim 5, wherein the second interfacial insulating film includes a third metal oxide layer and a fourth metal oxide layer sequentially stacked on the second inserted insulating film, and
wherein the third metal oxide layer and the fourth metal oxide layer include different metal materials.

7. The capacitor structure of claim 1, wherein the electrode structure includes at least one of Pt, Ir, Ru, Mo, V, TiN, NbN, TiSiN, MoN, VN, and ScN.

8. The capacitor structure of claim 1, wherein the first inserted insulating film includes at least one of Al₂O₃, Y₂O₃, MgO, Sc₂O₃, and SiO₂.

9. The capacitor structure of claim 1, wherein the first interfacial insulating film includes at least one of TiO₂, NbO, MoO₂, VO₂, ScO, TaO, Al₂O₃, and SnO₂.

10. The capacitor structure of claim 1, wherein the dielectric film includes at least one of ZrO₂, HfO₂, ZrHfO, TiO₂, Al₂O₃, GeO₂, Y₂O₃, MgO, and Sc₂O₃.

11. A capacitor structure comprising:
an electrode structure including a first electrode and a second electrode on the first electrode;
a dielectric film disposed between the first electrode and the second electrode and including a first material having a first oxidation number;
a first interfacial insulating film disposed between the first electrode and the dielectric film and including a second material having a second oxidation number; and
a first inserted insulating film disposed between the first electrode and the first interfacial insulating film,
wherein each of the dielectric film and the first interfacial insulating film includes a material having a rutile phase, and
wherein the first oxidation number is equal to the second oxidation number.

12. The capacitor structure of claim 11, wherein the first interfacial insulating film includes a third material having a third oxidation number different from the first oxidation number,
wherein a content of the second material in the first interfacial insulating film is higher than a content of the third material in the first interfacial insulating film.

13. The capacitor structure of claim 11, wherein the first inserted insulating film includes a material having an oxidation number different from each of the first and second oxidation numbers.

14. The capacitor structure of claim 11, wherein the first inserted insulating film is free of a rutile phase material.

15. The capacitor structure of claim 11, wherein an oxygen content in the first electrode is smaller than an oxygen content in the first interfacial insulating film.

16. The capacitor structure of claim 11, further comprising:
a second interfacial insulating film disposed between the second electrode and the dielectric film; and
a second inserted insulating film disposed between the second electrode and the second interfacial insulating film,
wherein a thickness of the first interfacial insulating film is greater than a thickness of the first inserted insulating film and is smaller than a thickness of the dielectric film, and
wherein a thickness of the second interfacial insulating film is greater than a thickness of the second inserted insulating film and is smaller than the thickness of the dielectric film.

17. The capacitor structure of claim 16, wherein each of the first interfacial insulating film and the second interfacial insulating film includes a plurality of metal oxide layers.

18. A semiconductor device comprising:
a substrate including a first source/drain area, a second source/drain area, and a word line trench defined between the first source/drain area and the second source/drain area;
a buried word line disposed in the word line trench;
a bit line connected to the first source/drain area; and
a capacitor structure connected to the second source/drain area,
wherein the capacitor structure includes:
an electrode structure including a lower electrode and an upper electrode on the lower electrode; and
a dielectric film structure disposed between the lower electrode and the upper electrode,
wherein the dielectric film structure includes:
a dielectric film including a rutile phase material and having a first thickness;
an interfacial insulating film disposed between the lower electrode and the dielectric film and having a second thickness smaller than the first thickness; and
an inserted insulating film disposed between the lower electrode and the interfacial insulating film, the inserted insulating film having a third thickness smaller than the second thickness.

19. The semiconductor device of claim 18, wherein the inserted insulating film includes at least one of Al₂O₃, Y₂O₃, MgO, Sc₂O₃, and SiO₂.

20. The semiconductor device of claim 18, wherein the interfacial insulating film includes at least one of TiO₂, NbO, MoO₂, VO₂, ScO, TaO, Al₂O₃, and SnO₂.
